(19) United States
(12) Patent Application Publication
(10) Pub. No.: US 2022/0075265 A1
(43) Pub. Date: Mar. 10, 2022

(54) Laminate, composition, and, laminate forming kit

(71) Applicant: FUJIFILM Corporation, Tokyo (JP)

(72) Inventor: Atsushi NAKAMURA, Haibara-gun (JP)

(73) Assignee: FUJIFILM Corporation, Tokyo (JP)

(21) Appl. No.: 17/479,439

(22) Filed: Sep. 20, 2021

Related U.S. Application Data
(63) Continuation of application No. PCT/JP2020/011329, filed on Mar. 16, 2020.

(30) Foreign Application Priority Data
Mar. 22, 2019 (JP) 2019-054620

(51) Int. Cl. G03F 7/09; G03F 7/038; C08L 51/00; G03F 7/32; C08F 216/06; C08F 226/10

(52) U.S. Cl. CPC G03F 7/094; G03F 7/0382; C08F 226/10; G03F 7/325; C08F 216/06; C08L 51/006

(57) ABSTRACT

Provided is a laminate that includes a base, an organic layer, a protective layer and a photo-sensitive layer in this order, the protective layer containing a resin, the resin having a branched part and a molecular chain bonded to the branched part, the molecular chain has at least one repeating unit from among repeating units represented by any of Formula (1-1) to Formula (5-1) below, the photo-sensitive layer being intended for development with use of a developing solution, and the protective layer being intended for stripping with use of a stripping solution; a composition intended for use in forming the protective layer or the photo-sensitive layer contained in the laminate; and, a laminate forming kit intended for use in forming the laminate, in the formula, R¹¹ represents a hydrogen atom or a methyl group, R²¹ represents a hydrogen atom or a methyl group, each of R³¹ to R³³ independently represents a substituent or a hydrogen atom, each of R⁴¹ to R⁴⁹ independently represents a substituent or a hydrogen atom, and each of R⁵¹ to R⁵⁴ independently represents a hydrogen atom or a substituent.

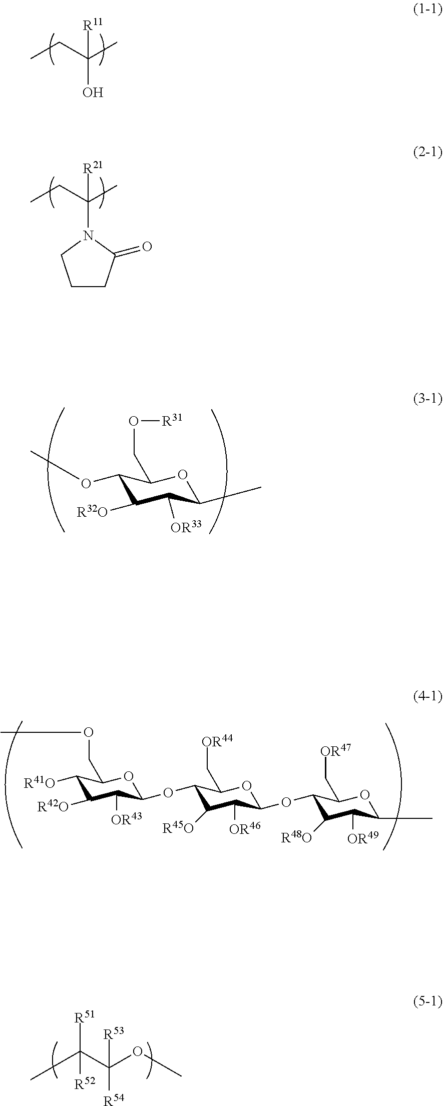

### CROSS-REFERENCE TO RELATED APPLICATIONS

This application is a Continuation of PCT International Application No. PCT/JP2020/011329 filed on Mar. 16, 2020, which claims priority under 35 U.S.C. § 119(a) to Japanese Patent Application No. 2019-054620 filed on Mar. 22, 2019. Each of the above application(s) is hereby expressly incorporated by reference, in its entirety, into the present application.

### BACKGROUND OF THE INVENTION

### 1. Field of the Invention

This invention relates to a laminate, a composition, and, a laminate forming kit.

### 2. Description of the Related Art

Devices making use of patterned organic layer have widely become popular in recent years, which are exemplified by semiconductor devices with use of organic semiconductor.

The devices with use of organic semiconductor typically enjoy features such as manufacture by easier processes as compared with prior devices with use of silicon or other inorganic semiconductors, and easy changeability of material characteristics through modification of molecular structure, and so forth. In addition, a great variety or the material suggests possibilities of functions and elements that could not have been achieved by inorganic semiconductors. The organic semiconductors are expected to be applicable to electronic devices including organic solar battery, organic electroluminescence display, organic photodetector, organic field effect transistor, organic electroluminescence device, gas sensor, organic rectifier, organic inverter and information recording device.

An organic layer in these organic semiconductors has been known to be patterned by using a laminate that contains the organic layer and a photo-sensitive layer (resist layer, for example).

For example, JP-2014-098889 A describes a resin composition that includes two or more kinds of resin having different principal chains with a hydroxy group, and water, aimed for use in formation of a protective film that protects a base or any film formed on the base, from a developing solution that contains an organic solvent, used for development during pattering.

JP-2015-087609 A describes a laminate that contains an organic semiconductor film, a protective film on the organic semiconductor film, and a resist film on the protective film, wherein the resist film is composed of a photo-sensitive resin composition that contains: (A) a photo-acid generator that produces an organic acid having a pKa of −1 or smaller; and (B) a resin whose dissolution rate, in a developing solution that contains an organic solvent, reduces in response to the acid generated from the photo-acid generator.

### CITATION LIST

### Patent Document

[Patent Document 1] JP-2014-098889 A

### SUMMARY OF THE INVENTION

As described above, the organic layer such as organic semiconductor layer has been patterned typically by a method in which the photo-sensitive layer is light exposed and developed to form a photo-sensitive layer pattern, and the protective layer and the organic layer are then etched through the photo-sensitive layer pattern which is used as a mask; or by a method in which the protective layer is developed with use of water or the like, through the photo-sensitive layer pattern which is used as a mask, and then the organic layer is patterned by etching through the protective layer pattern which is used as a mask.

In these methods, it has been a common practice to conduct post-etching removal of the protective layer with use of a stripping solution such as water, with a persistent need for good removability of the protectively layer.

It is therefore an object of this invention to provide a laminate that excels in post-etching removability of the protective layer, a composition intended for use in forming the protective layer or the photo-sensitive layer contained in the laminate, and, a laminate forming kit intended for use in forming the laminate.

Representative embodiments of this invention will be enumerated below.

<1> A laminate that includes a base, an organic layer, a protective layer and a photo-sensitive layer in this order,

the protective layer containing a resin,

the resin having a branched part and a molecular chain bonded to the branched part,

the resin being a water-soluble resin,

the photo-sensitive layer being intended for development with use of a developing solution, and

the protective layer being intended for stripping with use of a stripping solution.

<2> The laminate of <1>, wherein the molecular chain has at least one repeating unit from among repeating units represented by any of Formula (1-1) to Formula (5-1) below;

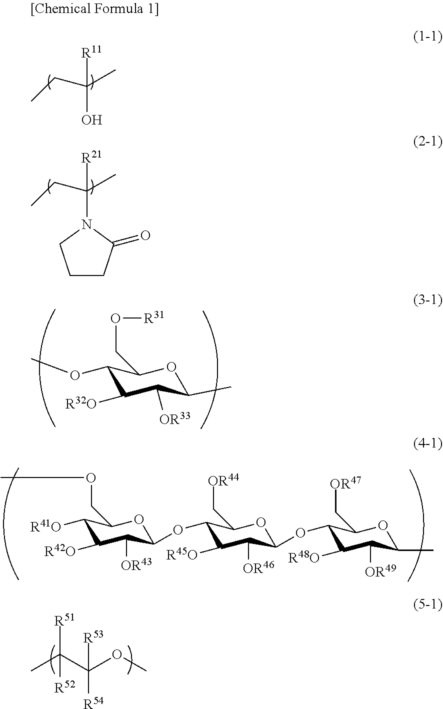

in Formula (1-1) to Formula (5-1), R¹¹ represents a hydrogen atom or a methyl group, R²¹ represents a hydrogen atom or a methyl group, each of R³¹ to R³³ independently represents a substituent or a hydrogen atom, each of R⁴¹ to R⁴⁹ independently represents a substituent or a hydrogen atom, and each of R⁵¹ to R⁵⁴ independently represents a hydrogen atom or a substituent.

<3> The laminate of <1> or <2>, wherein the resin is a water-soluble resin.

<4> The laminate of any one of <1> to <3>, wherein a component ratio the repeating unit in the molecular chain is 10 mol % or more different from a component ratio of the repeating unit in other molecular chain in the resin.

<5> The laminate of any one of <1> to <4>, wherein the molecular chain has a repeating unit represented by Formula (1-1), or, a repeating unit represented by Formula (2-1).

<6> The laminate of any one of <1> to <5>, wherein the resin is polyvinyl alcohol-grafted polyvinylpyrrolidone, or, polyethylene glycol-graft-polyvinyl alcohol.

<7> The laminate of any one of <1> to <6>, wherein the protective layer further contains other resin different from the resin.

<8> The laminate of any one of <1> to <7>, wherein the development is of negative type.

<9> The laminate of any one of <1> to <8>, wherein the developing solution contains an organic solvent whose content, relative to the total mass of the developing solution, is 90 to 100% by mass.

<10> A composition intended for use in forming the protective layer contained in the laminate described in any one of <1> to <9>, the composition includes:

a resin,

the resin having a branched part and a molecular chain bonded to the branched part, and

the resin being a water-soluble resin.

<11> A composition intended for use in forming the photo-sensitive layer contained in the laminate described in any one of <1> to <9>.

<12> A laminate forming kit includes A and B below:

A: a composition intended for use in forming the protective layer contained in the laminate described in any one of <1> to <9>, the composition includes a resin, the resin having a branched part and a molecular chain bonded to the branched part, and the resin being a water-soluble resin; and

B: a composition intended for use in forming the photo-sensitive layer contained in the laminate described in any one of <1> to <9>.

### Advantageous Effects of Invention

According to this invention, there is provided a laminate that excels in post-etching removability of the protective layer, a composition intended for use in forming the protective layer or the photo-sensitive layer contained in the laminate, and, a laminate forming kit intended for use in forming the laminate.

### BRIEF DESCRIPTION OF THE DRAWING

FIG. 1 is a cross-sectional view schematically illustrating work processes of a laminate according to a preferred embodiment of this invention.

### DETAILED DESCRIPTION OF THE PREFERRED EMBODIMENTS

This invention will be detailed below.

Note that all numerical ranges given in this patent specification, with use of “to” preceded and succeeded by numerals, are defined to represent ranges that contain these numerals as the lower limit value and the upper limit value, respectively.

Any notation of group (atomic group) in this patent specification, without special discrimination between substituted and unsubstituted, is understood to be both of group (atomic group) free of substituent and group (atomic group) having substituent. For example, notation of “alkyl group” not only encompasses an alkyl group free of substituent (unsubstituted alkyl group) but also encompasses an alkyl group having substituent (substituted alkyl group).

In this patent specification, “exposure” encompasses not only exposure with use of light, but also encompasses drawing with particle beam such as electron beam or ion beam, unless otherwise specifically noted. The light used for exposure is exemplified by active ray or radiation beam, such as bright line spectrum of mercury lamp, deep-UV radiation represented by excimer laser, extreme UV (EUV) radiation, X-ray and electron beam.

In this patent specification, “(meth)acrylate” represents both of acrylate and methacrylate, or either of them, “(meth)acryl” represents both of acryl and methacryl, or either of them, and “(meth)acryloyl” represents both of acryloyl and methacryloyl, or either of them.

In this patent specification, Me in structural formula represents methyl group, Et represents ethyl group, Bu represents butyl group, and Ph represents phenyl group.

In this patent specification, weight-average molecular weight (Mw) and number-average molecular weight (Mn) of water-soluble resin, such as polyvinyl alcohol, are polyethylene oxide (PEO) equivalent value measured by GPC (gel permeation chromatography) method, unless otherwise specifically noted.

In this patent specification, weight-average molecular weight (Mw) and number-average molecular weight (Mn) of water-insoluble resin, such as (meth)acryl resin, are polystyrene equivalent values measured by the GPC method, unless otherwise specifically noted.

In this patent specification, total solid content means total mass of components in the composition, excluding solvent.

In this patent specification, the term “process” encompasses not only independent processes, but also encompasses any processes so far as an expected operation is attainable, even if the processes are not clearly discriminable from the other processes.

In this patent specification, notations of “upper” and “lower” may only represent the upper part and lower part of that structure. That is, both parts may hold other structure in between, and are not always necessarily brought into contact. Note that the direction viewed from the organic layer towards the photo-sensitive layer is defined to be “upper”, meanwhile the direction viewed from the organic layer towards the base is defined to be “lower”, unless otherwise specifically noted.

In this patent specification, any component contained in the composition may contain two or more kinds of compound that correspond to the component, unless otherwise specifically noted. Also, content of each component in the composition means the total content of all compounds that correspond to the component, unless otherwise specifically noted.

In this patent specification, wavy line or * (asterisk) in the structural formulae indicates a site of bond formation with other structure, unless otherwise specifically noted.

Atmospheric pressure in this invention is 101,325 Pa (1 atom), unless otherwise specifically noted. Temperature in this invention is 23° C., unless otherwise specifically noted.

In this patent specification, combination of preferred embodiments will give a more preferred embodiment.

### (Laminate)

A laminate of this invention includes a base, an organic layer, a protective layer and a photo-sensitive layer in this order,

the protective layer contains a resin,

the resin having a branched part and a molecular chain bonded to the branched part,

the resin is a water-soluble resin,

the photo-sensitive layer is intended for development with use of a developing solution, and

the protective layer is intended for stripping with use of a stripping solution.

Hereinafter, the resin which has the branched part and the molecular chain bonded to the branched part, and is water-soluble, will be also referred to as a “specific resin”.

The laminate of this invention excels in post-etching removability of the protective layer. The reason why this effect is obtainable is supposedly as follows.

Methods for patterning the organic layer having been practiced include a method in which a water-soluble resin such as straight-chain polyvinyl alcohol (PVA) is used as the protective layer, the protective layer and the organic layer are partially removed by etching through a mask pattern formed of the photo-sensitive layer, and the protective layer is then removed with use of a stripping solution; and, a method in which the protective layer is developed with use of water or the like through a mask pattern formed of the photo-sensitive layer, the organic layer is partially removed by etching through a mask pattern formed of the protective layer, and the protective layer is then removed with use of a stripping solution.

The present inventors found that the protective layer occasionally suffered from lowered post-etching removability with use of a stripping solution.

This is supposedly because PVA or the like, contained in the protective layer within an area brought into contact typically with an etching gas, would polymerize to make the protective layer less removable with use of a stripping solution such as water (or, less soluble to a stripping solution such as water).

The present inventors found from our thorough investigations that, with a specific resin contained therein, the protective layer becomes excellent in post-etching removability of the protective layer.

Although the reason remains not thoroughly clear, the specific resin is featured by its specific structure having a branched part and a molecular chain bonded to the branched part, and is water-soluble. Hence, such specific resin, even if should have been polymerized, is supposedly less likely to degrade the removability with use of a stripping solution such as water.

Patent Document 1 neither describes nor suggests that the protective layer contains the specific resin.

The laminate of this invention is applicable to patterning of the organic layer contained in the laminate.

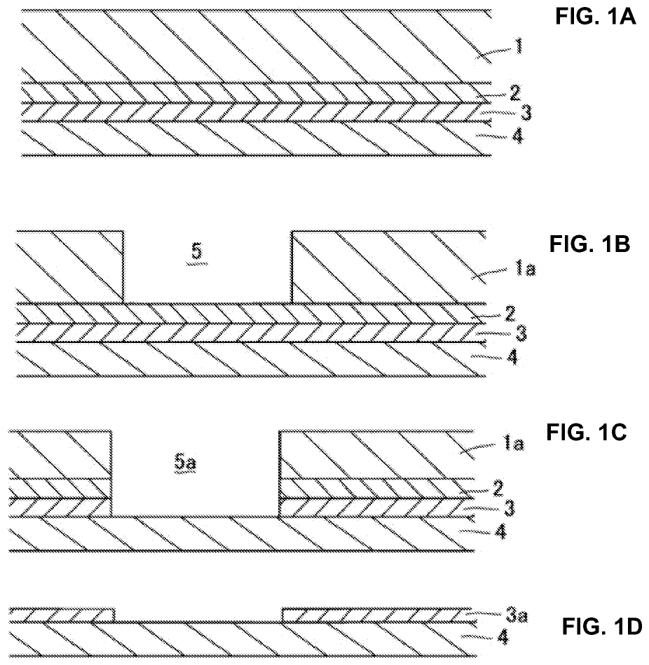

FIG. 1 is a cross-sectional view schematically illustrating work processes of a laminate according to a preferred embodiment of this invention. In one embodiment of this invention exemplified in FIG. 1A, an organic layer 3 (organic semiconductor layer, for example) is arranged on a base 4. A protective layer 2 that protects the organic layer 3 is further arranged in contact with the surface of the organic layer 3. Although some other layer may be interposed between the organic layer 3 and the protective layer 2, an exemplary preferred embodiment relates to that the organic layer 3 and the protective layer 2 are brought into direct contact, from the viewpoint of more easily achieving the effect of this invention. On the protective layer, further arranged is a photo-sensitive layer 1. The photo-sensitive layer 1 and the protective layer 2 may be in direct contact, or some other layer may be interposed between the photo-sensitive layer 1 and the protective layer 2.

FIG. 1B illustrates an exemplary case where a part of the photo-sensitive layer 1 is light-exposed and developed. For example, the photo-sensitive layer 1 is partially light-exposed typically by a method with use of a predetermined mask or the like, and then developed after the exposure by using a developing solution such as an organic solvent, thereby removing the photo-sensitive layer 1 in a removal area 5, and forming the photo-sensitive layer 1a after exposure and development. Since the protective layer 2 remains less soluble to the developing solution, so that the organic layer 3 is protected by the protective layer 2, from being damaged by the developing solution.

FIG. 1C illustrates an exemplary case where parts of the protective layer 2 and the organic layer 3 are removed. For example, the protective layer 2 and the organic layer 3 are removed typically by dry etching in the removal area 5 where the photo-sensitive layer (resist) la has been removed by development, whereby a removal area 5a is formed in the protective layer 2 and the organic layer 3. The organic layer 3 may be thus removed in the removal area 5a. That is, the organic layer 3 can be patterned.

FIG. 1D illustrates an exemplary case where the photo-sensitive layer 1a and the protective layer 2 are removed after the patterning. For example, the photo-sensitive layer 1a and the protective layer 2 are removed from the organic layer 3a after processed, by washing off the photo-sensitive layer 1a and the protective layer 2 in the laminate, as illustrated in FIG. 1C, with a stripping solution that contains water.

As illustrated above, a preferred embodiment of this invention can form a desired pattern in the organic layer 3, and can remove the photo-sensitive layer 1 as the resist, and the protective layer 2 as the protective film. These processes will be detailed later.

### <Base>

The laminate of this invention contains a base.

The base is exemplified by those made of various materials including silicon, quartz, ceramic, glass, polyester films such as polyethylene naphthalate (PEN) and polyethylene terephthalate (PET), and polyimide film, which is freely selectable depending on applications. For example, when intended for flexible devices, a base made of a flexible material may be used. The base may also be a composite base made of a plurality of materials, or may be a multi-layered base having a plurality of materials stacked therein.

The base may have any geometry which is selectable without special limitation depending on applications, and is exemplified by plate-like base (also referred to as “substrate”, hereinafter). Also thickness of the substrate is not specifically limited.

### <Organic Layer>

The laminate of this invention contains an organic layer.

The organic layer is exemplified by organic semiconductor layer and resin layer.

In the laminate of this invention, the organic layer may only be contained on the upper side of the base, allowing direct contact between the base and the organic layer, or interposition of some other layer between the organic layer and the base.

### [Organic Semiconductor Layer]

The organic semiconductor layer is a layer that contains an organic material that demonstrates semiconductor characteristic (also referred to as “organic semiconductor compound”).

### —Organic Semiconductor Compound—

Like semiconductors composed of inorganic materials, the organic semiconductor compound includes p-type organic semiconductor compound in which hole moves as a carrier, and n-type organic semiconductor compound in which electron moves as a carrier.

Ease of move of the carriers in the organic semiconductor layer is given by carrier mobility p. Although depending on use, high mobility is usually preferred, which is preferably 10⁻⁷ cm²/Vs or larger, more preferably 10⁻⁶ cm²/Vs or larger, and even more preferably 10⁻⁵ cm²/Vs or larger. The mobility o may be determined on the basis of characteristics of field effect transistor (FET) device manufactured therefrom, or by the time-of-flight (TOF) method.

The p-type organic semiconductor compound applicable to the organic semiconductor layer is freely selectable from organic semiconductor materials that demonstrate hole transportability, and is preferably any of p-type r-conjugated polymer compounds {for example, substituted or unsubstituted polythiophene (for example, poly(3-hexylthiophene) (P3HT, from Sigma-Aldrich Japan), etc., polyselenophene, polypyrrole, polyparaphenylene, poly(paraphenylene vinylene), poly(thiophene vinylene), polyaniline, etc.}; condensed polycyclic compounds (for example, substituted or unsubstituted anthracene, tetracene, pentacene, anthradithiophene, hexabenzocoronene, etc.); triarylamine compounds {for example, m-MTDATA (4,4′,4″-tris[(3-methylphenyl)phenylamino] triphenylamine), 2-TNATA (4,4′,4″-tris[2-naphthyl(phenyl)amino] triphenylamine), NPD (N,N′-di[(1-naphthyl)-N,N′-diphenyl]-1,1′-biphenyl)-4,4′-diamine), TPD (N,N′-diphenyl-N,N′-di(m-tolyl)benzidine), mCP (1,3-bis(9-carbazolyl)benzene), CBP (4,4′-bis(9-carbazolyl)-2,2′-biphenyl), etc.}; five-membered heterocyclic compounds (for example, substituted or unsubstituted oligothiophene, TTF (tetrathiafulvalene), etc.); phthalocyanine compounds (substituted or unsubstituted phthalocyanine, naphthalocyanine, anthracyanine and tetrapyrazinoporphyrazine having various center metals); porphyrin compounds (substituted or unsubstituted porphyrins with various center metals); carbon nanotube, carbon nanotube modified with semiconductor polymer, and graphene. The p-type organic semiconductor compound is more preferably any of p-type n-conjugated polymer compounds, condensed polycyclic compound, triarylamine compounds, five-membered heterocyclic compounds, phthalocyanine compounds, and porphyrin compound, and even more preferably any of p-type n-conjugated polymer compounds.

The n-type semiconductor compound applicable to the organic semiconductor layer is freely selectable from organic semiconductor materials that demonstrate electron transportability, and is preferably any of fullerene compound, electron-deficient phthalocyanine compound, naphthalene tetracarbonyl compound, perylene tetracarbonyl compound, TCNQ (tetracyanoquinodimethane) compound, hexaazatriphenylene compound, polythiophene compound, benzidine compound, carbazole compound, phenanthroline compound, perylene compound, aluminum-based compound with quinolinol ligand, iridium-based compound with phenylpyridine ligand, and n-type n-conjugated polymer compound. The n-type organic semiconductor compound is more preferably any of fullerene compound, electron-deficient phthalocyanine compound, naphthalene tetracarbonyl compound, perylene tetracarbonyl compound and n-type n-conjugated polymer compound; and particularly preferably any of fullerene compound, hexaazatriphenylene compound, and n-type n-conjugated polymer compound. In this invention, the fullerene compound means substituted or unsubstituted fullerene, an may be any of C₆₀, C₇₀, C₇₆, C₇₈, C₈₀, C₈₂, C₈₄, C₈₆, C₈₈, C₉₀, C₉₆, C₁₁₆, C₁₈₀, C₂₄₀ and C₅₄₀ fullerenes, among which preferred are substituted or unsubstituted C₆₀, C₇₀ and C₈₆ fullerenes, and particularly preferred are PCBM ([6,6]-phenyl-C₆₁-butyric acid methyl ester, from Sigma-Aldrich Japan, etc.), and analogues thereof (those having C₆₀ moiety substituted by C₇₀, C₈₆ or the like, those having substituent benzene rings substituted by other aromatic or heterocycle, and those having methyl ester substituted by n-butyl ester, i-butyl ester or the like).

The electron-deficient phthalocyanine compound is exemplified by phthalocyanines with various center metals having four or more electron attractive groups bound thereto (F₁₆MPc, FPc-S8, etc., where M represents center metal, Pc represents phthalocyanine, and S8 represents n-octylsulfonyl group), naphthalocyanine, anthracyanine, substituted or unsubstituted tetrapyrazinoporphyrazine, and so forth. The naphthalene tetracarbonyl compound, although not specifically limited, is preferably naphthalene tetracarboxylic anhydride (NTCDA), naphthalene bisimido compound (NTCDI), or perinone pigments (Pigment Orange 43, Pigment Red 194, etc.).

The perylene tetracarbonyl compound, although not specifically limited, is preferably perylene tetracarboxylic dianhydride (PTCDA), perylene diimido compound (PTCDI), and benzimidazole fused ring (PV).

TCNQ compound means substituted or unsubstituted TCNQ, as well as TCNQ having benzene ring moiety substituted by other aromatic ring or heterocycle, and is exemplified by TCNQ, TCNAQ (tetracyanoquinodimethane), and TCN3T (2,2′-((2E,2″E)-3′,4′-alkyl substituted-5H,5″H-[2,2′:5′,2″-terthiophene]-5,5″-diylidene)dimalononitrile derivatives). Graphene is also exemplified.

The hexaazatriphenylene compound means compounds having a 1,4,5,8,9,12-hexaazatriphenylene skeleton, and is preferably exemplified by 2,3,6,7,10,11-hexacyano-1,4,5,8,9,12-hexaazatriphenylene (HAT-CN).

The polythiophene-based compound means compounds having a polythiophene structure such as poly(3,4-ethylenedioxythiophene), and is exemplified by PEDOT:PSS (complex composed of poly(3,4-ethylenedioxythiophene) (PEDOT) and polystyrenesulfonic acid (PSS)).

The benzidine compound means compounds having a benzidine structure in the molecule, and is exemplified by N,N′-bis(3-methylphenyl)-N,N′-diphenylbenzidine(TPD), N,N′-di-[(1-naphthyl)-N,N′-diphenyl]-1,1′-biphenyl)-4,4′-diamine (NPD).

The carbazole-based compound means compounds having a carbazole ring structure in the molecule, and is exemplified by 4,4′-bis(N-carbazolyl)-1,1′-biphenyl (CBP).

The phenanthroline compound means compounds having a phenanthroline ring structure in the molecule, and is exemplified by 2,9-dimethyl-4,7-diphenyl-1,10-phenanthroline (BCP).

The iridium compound with phenylpyridine ligand means compounds having an iridium complex structure coordinated with phenylpyridine structure as the ligand, and is exemplified by bis(3,5-difluoro-2-(2-pyridylphenyl-(2-carboxypyridyl)iridium(III) (FIrpic), and tris(2-phenylpyridinato)iridium(III) (Ir(ppy)₃).

The aluminum compound with quinolinol ligand means compounds having an aluminum complex structure coordinated with quinolinol structure as the ligand, and is exemplified by tris(8-quinolinolato)aluminum.

Particularly preferred examples of the n-type organic semiconductor compound are enumerated below.

Note that R in the formulae, although not specifically limited, preferably represents any of a hydrogen atom, a substituted or unsubstituted, branched or straight-chain alkyl group (preferably having 1 to 18 carbon atoms, more preferably 1 to 12, and even more preferably 1 to 8 carbon atoms), or a substituted or unsubstituted aryl group (preferably having 6 to 30 carbon atoms, more preferably 6 to 20, and even more preferably 6 to 14 carbon atoms). In the structural formulae, Me represents a methyl group, and M represents a metal element.

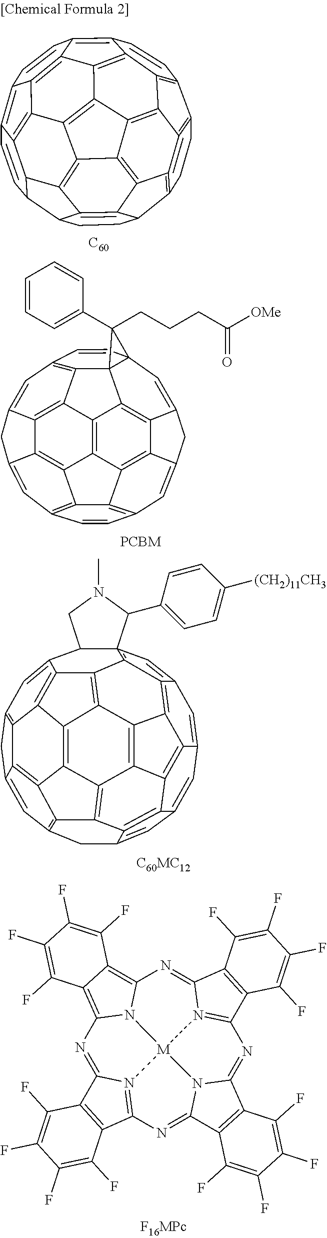

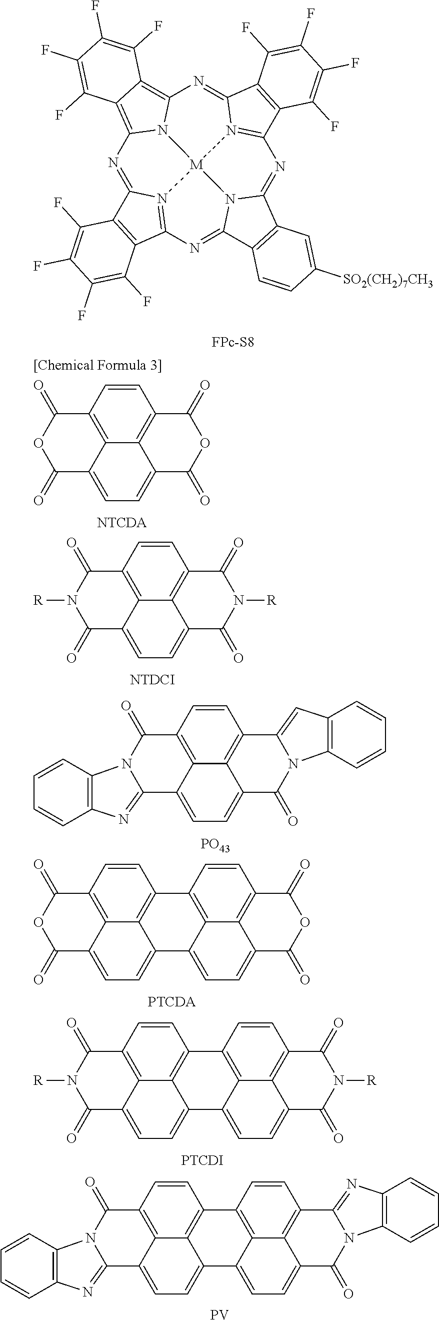

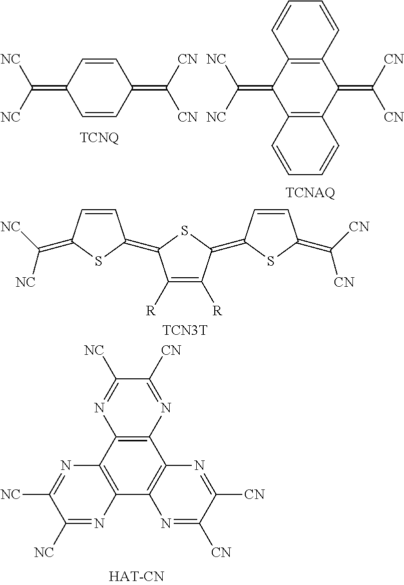

One kind of, or two or more kinds of the organic semiconductor compound may be contained in the organic semiconductor layer.

Content of the organic semiconductor compound, relative to the total mass of the organic semiconductor layer, is preferably 1 to 100% by mass, and more preferably 10 to 100% by mass.

### —Binder Resin—

The organic semiconductor layer may further contain a binder resin.

The binder resin is exemplified by insulating polymers such as polystyrene, polycarbonate, polyarylate, polyester, polyamide, polyimide, polyurethane, polysiloxane, polysulfone, polymethyl methacrylate, polymethyl acrylate, cellulose, polyethylene and polypropylene, and copolymers of them; photo-conductive polymers such as polyvinyl carbazole and polysilane; and conductive polymers such as polythiophene, polypyrrole, polyaniline, and polyparaphenylene vinylene.

The organic semiconductor layer may contain one kind of, or two or more kinds of binder resin. Taking mechanical strength of the organic semiconductor layer into consideration, preferred is a binder resin having high glass transition temperature. Meanwhile, taking the charge mobility into consideration, preferred is a binder resin composed of photo-conductive polymer or conductive polymer, free of polar group in the structures.

Content of the binder resin, when contained in the organic semiconductor layer, is preferably 0.1 to 30% by mass relative to the total mass of the organic semiconductor layer.

### —Film Thickness—

Film thickness of the organic semiconductor layer can vary without special limitation, depending typically on types of device to be finally manufactured, and is preferably 5 nm to 50 μm, more preferably 10 nm to 5 μm, and even more preferably 20 nm to 500 nm.

### —Organic Semiconductor Layer Forming Composition—

The organic semiconductor layer is formed typically by using an organic semiconductor layer forming composition that contains a solvent and an organic semiconductor compound.

One exemplary method for forming is such as applying the organic semiconductor layer forming composition over the base to form a layer, and then drying it to form a film. For a method for application, a description regarding a method for applying the protective layer forming composition for the later-described protective layer may be referred to.

The solvent contained in the organic semiconductor layer forming composition is exemplified by hydrocarbon solvents such as hexane, octane, decane, toluene, xylene, ethyl benzene, and 1-methylnaphthalene; ketone solvents such as acetone, methyl ethyl ketone, methyl isobutyl ketone, and cyclohexanone; halogenated hydrocarbon solvents such as dichloromethane, chloroform, tetrachloromethane, dichloroethane, trichloroethane, tetrachloroethane, chlorobenzene, dichlorobenzene, and chlorotoluene; ester solvents such as ethyl acetate, butyl acetate, and amyl acetate; alcohol solvents such as methanol, propanol, butanol, pentanol, hexanol, cyclohexanol, methylcellosolve, ethyl cellosolve, and ethylene glycol; ether solvents such as dibutyl ether, tetrahydrofuran, dioxane and anisole; and polar solvent such as N,N-dimethylformamide, N,N-dimethylacetamide, 1-methyl-2-pyrrolidone, 1-methyl-2-imidazolidinone, and dimethyl sulfoxide. Only one kind of, or two or more kinds of solvent may be used.

Content of the organic semiconductor compound relative to the total mass of the organic semiconductor layer forming composition is preferably 0.1 to 80% by mass, and more preferably 0.1 to 30% by mass. The content of the organic semiconductor may suitably be determined depending typically on desired thickness of the organic semiconductor layer.

The organic semiconductor layer forming composition may further contain the aforementioned binder resin.

The binder resin may be dissolved, or dispersed in a solvent contained in the organic semiconductor layer forming composition.

Content of the binder, if contained in the organic semiconductor layer forming composition, is preferably 0.1 to 30% by mass, relative to the total solid content of the organic semiconductor layer forming composition.

The organic semiconductor layer forming composition may further contain a semiconductor material other than the organic semiconductor compound, or may contain other additive. Use of such other semiconductor material, or, an organic semiconductor layer forming composition that contains such other additive enables formation of a blend film that contains such other semiconductor material, or, such other additive.

For example, the organic semiconductor layer forming composition that further contains such other semiconductor material may be used, typically in a case where a photo-electric conversion layer is manufactured.

During formation of the film, the base may be heated or cooled. By changing the temperature of the base, it now becomes possible to control film quality of the organic semiconductor layer, or molecular packing in the film. The temperature of the base, although not specifically limited, is preferably −200° C. to 400° C., more preferably −100° C. to 300° C., and even more preferably 0° C. to 200° C.

The thus formed organic semiconductor layer may be post-processed to control the property. Possible processes may be such that subjecting the thus formed organic semiconductor layer to heating, or exposure to an evaporated solvent, so as to modify the film morphology or molecular packing in the film, thereby obtaining a desired property. Also carrier density in the film is controllable by exposing the thus formed organic semiconductor layer to a substance such as oxidizing or reductive gas or solvent, or by mixing them to cause an oxidation or reduction.

### [Resin Layer]

The resin layer is an organic layer other than the organic semiconductor layer, and contains a resin.

The resin contained in the resin layer is exemplified by, but not specifically limited to, (meth)acryl resin, ene-thiol resin, polycarbonate resin, polyether resin, polyarylate resin, polysulfone resin, polyethersulfone resin, polyphenylene resin, polyarylene ether phosphine oxide resin, polyimide resin, polyamide-imide resin, polyolefin resin, cyclic olefin resin, polyester resin, styrene resin, polyurethane resin, and polyurea resin.

Among them, (meth)acryl resin is preferred from the viewpoint that the effect of this invention is easily obtainable.

The resin contained in the resin layer is preferably water-insoluble, preferably demonstrating an amount of dissolution at 25° C., into 100 g of water, of 0.1 g or less, which is more preferably 0.01 g or less.

The resin layer may contain, other than the resin, any of known additives such as colorant, dispersant, refractive index modifier, or the like. Types and contents of these additives may be properly determined, referring to known techniques, and depending on applications.

Applications of the resin layer are exemplified by coloring layer for color filter and so forth, high refractive index layer or low refractive index layer such as refractive index modification layer, and insulating layer for wiring.

### —Film Thickness—

Film thickness of the resin layer is not specifically limited, and may vary depending on types of device to be finally manufactured or types of the organic layer per se, which is preferably 5 nm to 50 μm, more preferably 10 nm to 5 μm, and even more preferably 20 nm to 500 nm.

—Resin Layer forming Composition—

The resin layer is typically formed by using a resin layer forming composition that contains the resin and a solvent. An exemplary method for forming is such as applying the resin layer forming composition over a base to form a layer, and then by drying it to form a film. Regarding method of application, for example, description on the later-described method of applying the protective layer forming composition for the protective layer may be referred to.

The resin layer may alternatively be formed by using a resin layer forming composition that contains a raw material of the resin. An exemplary method is such as applying a resin layer forming composition that contains, as a raw material of the resin, a resin which is a precursor of the resin, or, a resin layer forming composition that contains a polymerizable compound (compound having a polymerizable group) that composes a monomer unit in the resin, and an optional polymerization initiator, over a base to form a layer, and then by converting the layer into a film at least either by drying or curing. For a method for application, a description regarding a method for applying the protective layer forming composition for the later-described protective layer may be referred to. Method for curing may rely upon any of known methods such as heating or light exposure, typically depending on types of the resin precursor, or types of the polymerization initiator.

### <Protective Layer>

The protective layer in this invention contains the specific resin.

The protective layer is preferably a layer that demonstrates the rate of dissolution at 23° C. into a developing solution of 10 nm/s or lower, which is more preferably 1 nm/s or lower. The lower limit of the rate of dissolution is not specifically limited, and may only be 0 nm/s or above.

### [Specific Resin]

The specific resin has a branched part, and a molecular chain bonded to the branched part.

The molecular chain preferably has a repeating unit, and preferably has at least one repeating unit from among the repeating units represented by any of formula (1-1) to Formula (5-1) explained later.

The specific resin is not specifically limited so long as it has the branched part, and has the molecular chain bonded to the branched part, and may be any of comb-like polymer (graft polymer), star branched polymer, or polymer having a pendant molecular chain, among which comb-like polymer or star branched polymer is preferred, and comb-like polymer is more preferred.

The specific resin, if being a comb-like polymer, preferably has the molecular chain as a side chain (grafted chain).

The specific resin is a water-soluble resin.

The water-soluble resin means a resin with a solubility of 1 g or more in 100 g of water at 23° C., wherein the solubility is preferably 5 g or more, even more preferably 10 g or more, and yet more preferably 30 g or more. The upper limit, although not specifically limited, is practically 100 g.

In this invention, also alcohol-soluble resin may be used as the water-soluble resin. The alcohol-soluble resin is exemplified by polyvinyl acetal. Alcohol usable as the solvent are selectable from those commonly used, and is exemplified by isopropanol. The alcohol-soluble resin means a resin with a solubility of 1 g or more in 100 g of alcohol (for example) at 23° C., wherein the solubility is preferably 10 g or more, and even more preferably 20 g or more. The upper limit, although not specifically limited, is practically 30 g or below. Note that in this invention, the alcohol-soluble resin is defined to be encompassed by the water-soluble resin, unless otherwise specifically noted.

### —Branched Part—

The specific resin may only have at least one branched part, preferably has 1 to 1,000, and more preferably has 10 to 100 branched parts per molecule.

The branched part is preferably a tri-functional or higher functional branched part, more preferably a tri- to penta-functional branched part, and even more preferably a tri-functional branched part. In this disclosure, f-functional branched part means a branched part at which f linear molecular chains are bonded. For example, a branched part indicated by * in a resin represented by the structural formula below is a tri-functional branched part. In the resin represented by the structural formula below, each of m, n and p independently represents an integer of 2 or larger, wherein m structural units and n structural units are randomly arranged.

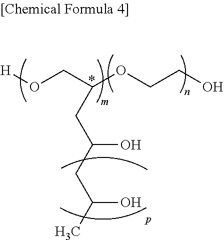

The branched part may be constituted by only one carbon atom as indicated by *, or may be constituted by a plurality of elements as represented by Formula (BR1) or Formula (BR2) below. In Formula (BR1) or Formula (BR2) below, each wavy line represents a site of bond formation with other structure. Both of the branched part represented by Formula (BR1) below, and the branched part represented by Formula (BR2) below are tri-functional branched parts.

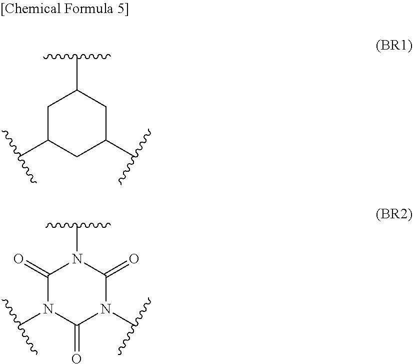 [SMILES: *C1CC(*)CC(*)C1 ; *n1c(=O)n(*)c(=O)n(*)c1=O]

Other structures of the branched part may be determined depending on the structure of the molecular chain, without special limitation.

### —Molecular Chain—

The molecular chain bonded to the branched part may be a molecular chain having a repeating unit, or may be a molecular chain free of repeating unit, wherein preferred is the molecular chain having a repeating unit.

The molecular chain free of repeating unit is exemplified by side chain in xanthan gum, but not limited thereto.

The molecular chain bonded to the branched part preferably has at least one repeating unit from among repeating units represented by any of Formula (1-1) to Formula (5-1).

Amon them, the molecular chain preferably has the repeating unit represented by Formula (1-1), or the repeating unit represented by Formula (2-1).

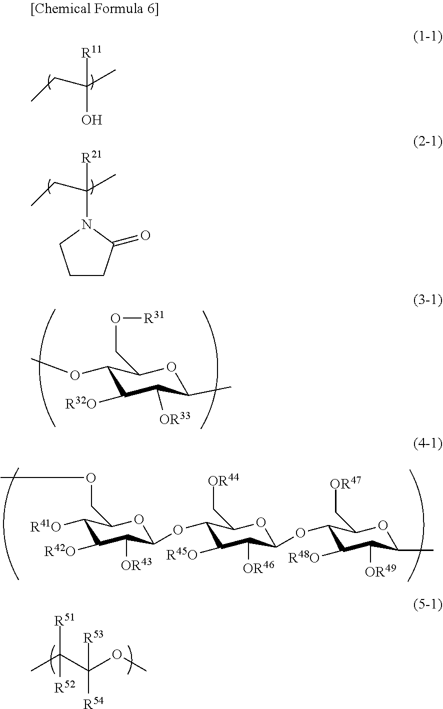

In Formula (1-1) to Formula (5-1), R¹¹ represents a hydrogen atom or a methyl group, R²¹ represents a hydrogen atom or a methyl group, each of R³¹ to R³³ independently represents a substituent or a hydrogen atom, each of R⁴¹ to R⁴⁹ independently represents a substituent or a hydrogen atom, and each of R⁵¹ to R⁵⁴ independently represents a hydrogen atom or a substituent.

The molecular chain may have an additional branched part, but is preferably free of the additional branched part. In a case where the molecular chain has the additional branched part, the molecular chain bonded to the branched part preferably has at least one of the repeating units represented by any of Formula (1-1) to Formula (5-1).

The molecular chain preferably has a weight average molecular weight (molecular weight of a moiety ranged from the branching point to the end of the molecular chain) of 1,000 to 50,000, which is more preferably 1,000 to 30,000.

<<Molecular Chain that Contains Repeating Unit Represented by Formula (1-1)>>

In Formula (1-1), R¹¹ preferably represents a hydrogen atom.

The molecular chain that contains the repeating unit represented by Formula (1-1) may further contain a repeating unit which is different from the repeating unit represented by Formula (1-1).

The molecular chain that contains the repeating unit represented by Formula (1-1) preferably contains 10% by mass to 100% by mass, relative to the total mass of the molecular chain, of the repeating unit represented by Formula (1-1), wherein the percentage is more preferably 40% by mass to 100% by mass.

The molecular chain that contains the repeating unit represented by Formula (1-1) is exemplified by a molecular chain that contains two types of repeating unit represented by Formula (1-2) below.

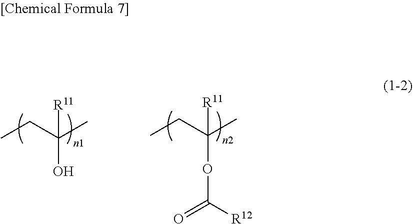

In Formula (1-2), each R¹¹ independently represents a hydrogen atom or a methyl group, R¹² represents a substituent, and each of n1 and n2 represents component ratio on the mass basis.

In Formula (1-2), R¹¹ is synonymous to R¹¹ in Formula (1-1), whose preferred embodiments are also same.

In Formula (1-2), R¹² is exemplified by a group represented by -L^{P}-T^{P}. L^{P} represents a single bond or a linking group L described later. T^{P} represents a substituent, and is exemplified by substituent T described later. In particular, R¹² preferably represents a hydrocarbon group such as alkyl group (whose number of carbon atoms is preferably 1 to 12, more preferably 1 to 6, and even more preferably 1 to 3), alkenyl group (whose number of carbon atoms is preferably 2 to 12, more preferably 2 to 6, and even more preferably 2 to 3), alkynyl group (whose number of carbon atoms is preferably 2 to 12, more preferably 2 to 6, and even more preferably 2 to 3), aryl group (whose number of carbon atoms is preferably 6 to 22, more preferably 6 to 18, and even more preferably 6 to 10), or aryl alkyl group (whose number of carbon atoms is preferably 7 to 23, more preferably 7 to 19, and even more preferably 7 to 11). These alkyl group, alkenyl group, alkynyl group, aryl group and aryl alkyl group may further have a group specified by substituent T, so far as the effect of this invention may be demonstrated.

In Formula (1-2), each of n1 and n2 represents component ratios, on the mass basis, in the molecule, and is independently 10% by mass or larger and smaller than 100% by mass. Note, however, (n1+n2) does not exceeds 100% by mass. With (n1+n2) fallen under 100% by mass, such resin means a copolymer that further contains other repeating unit.

<<Molecular Chain that Contains Repeating Unit Represented by Formula (2-1)>>

In Formula (2-1), R²¹ preferably represents a hydrogen atom.

The molecular chain that contains the repeating unit represented by Formula (2-1) may further contain a repeating unit which is different from the repeating unit represented by Formula (2-1).

The molecular chain that contains the repeating unit represented by Formula (2-1) preferably contains 10% by mass to 100% by mass of the repeating unit represented by Formula (2-1), relative to the total mass of the molecular chain, wherein the percentage is more preferably 40% by mass to 100% by mass.

The molecular chain that contains the repeating unit represented by Formula (2-1) is exemplified by a molecular chain that contains two types of repeating unit represented by Formula (2-2) below.

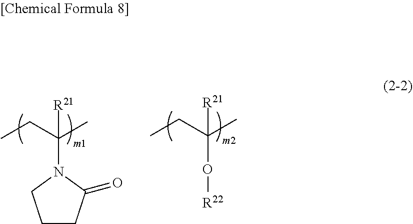

In Formula (2-2), each of R²¹ independently represents a hydrogen atom or a methyl group, R²² represents a substituent, and each of m1 and m2 represents component ratio, on the mass basis, in the molecule.

In Formula (2-2), R²¹ is synonymous to R²¹ in Formula (2-1), whose preferred embodiments are also same.

In Formula (2-2), R²² is exemplified by a group represented by -L^{P}-T^{P}. L^{P} represents a single bond or a linking group L described later. T^{P} represents a substituent, and is exemplified by substituent T described later. In particular, R²² is preferably any of hydrocarbon group exemplified by alkyl group (whose number of carbon atoms is preferably 1 to 12, more preferably 1 to 6 and even more preferably 1 to 3), alkenyl group (whose number of carbon atoms is preferably 2 to 12, more preferably 2 to 6, and even more preferably 2 to 3), alkynyl group (whose number of carbon atoms is preferably 2 to 12, more preferably 2 to 6, and even more preferably 2 to 3), aryl group (whose number of carbon atoms is preferably 6 to 22, more preferably 6 to 18, and even more preferably 6 to 10), or, aryl alkyl group (whose number of carbon atoms is preferably 7 to 23, more preferably 7 to 19, and even more preferably 7 to 11). These alkyl group, alkenyl group, alkynyl group, aryl group, and arylalkyl group may further have a group specified by substituent T, so far as the effect of this invention may be demonstrated.

In Formula (2-2), each of m1 and m2 represents component ratio, on the mass basis, in the molecule, wherein m1 represents 10% by mass larger and 100% by mass or smaller, and m2 represents 0% by mass or larger and smaller than 100% by mass. That is, m2 may represent 0% by mass. Note that (m1+m2) does not exceed 100% by mass. With (m1+m2) fallen under 100% by mass, such resin means a copolymer that further contains any other repeating unit.

<<Molecular Chain that Contains Repeating Unit Represented by Formula (3-1)>>

In Formula (3-1), each of R³¹ to R³³ independently and preferably represents an optionally substituted hydrocarbon group, acyl group, —(CH₂CH₂O)ₘₐH, —CH₂COONa or hydrogen atom, more preferably represents a hydrocarbon group, hydrocarbon group having hydroxy group as a substituent, acyl group or hydrogen atom, and even more preferably represents a hydrogen atom. ma Represents 1 or 2.

The optionally substituted hydrocarbon group preferably has 1 to 10 carbon atoms, and more preferably 1 to 4 carbon atoms.

The hydrocarbon group having hydroxy group as a substituent is preferably a hydrocarbon group having one hydroxy group and 1 to 10 carbon atoms, more preferably a hydrocarbon group having one hydroxy group and 1 to 4 carbon atoms, and even more preferably —CH₂(OH), —CH₂CH₂(OH) or —CH₂CH(OH)CH₃.

The acyl group is preferably an alkylcarbonyl group whose alkyl moiety having 1 to 4 carbon atoms, and more preferably acetyl group.

The resin that contains the repeating unit represented by Formula (3-1) may further contain a repeating unit different from the repeating unit represented by Formula (3-1).

The resin that contains the repeating unit represented by Formula (3-1) preferably contains 10% by mass to 100% by mass, relative to the total mass of the molecular chain, of the repeating unit represented by Formula (3-1), wherein the percentage is more preferably 40% by mass to 100% by mass.

The hydroxy group depicted in Formula (3-1) may suitably be substituted by the substituent T, or by a group having combined therein the substituent T and a linking group L. A plurality of substituents T, if any, may bond to each other, or may bond to the ring depicted in the formula while being interposed by, or without being interposed by the linking group L, to form a ring.

<<Molecular Chain that Contains Repeating Unit Represented by Formula (4-1)>>

In Formula (4-1), each of R⁴¹ to R⁴⁹ independently and preferably represents an optionally-substituted hydrocarbon group, acyl group, —(CH₂CH₂O)ₘₐH, —CH₂COONa or hydrogen atom; more preferably represents a hydrocarbon group, hydrocarbon group having hydroxy group as a substituent, acyl group or hydrogen atom; and even more preferably represents a hydrogen atom. ma Represents 1 or 2.

The optionally-substituted hydrocarbon group preferably has 1 to 10 carbon atoms, and more preferably has 1 to 4 carbon atoms.

The hydrocarbon group having hydroxy group as a substituent is preferably a hydrocarbon group having one hydroxy group and 1 to 10 carbon atoms, more preferably a hydrocarbon group having one hydroxy group and 1 to 4 carbon atoms, and even more preferably —CH₂(OH), —CH₂CH₂(OH) or —CH₂CH(OH)CH₃.

The molecular chain that contains the repeating unit represented by Formula (4-1) may further contain a repeating unit which is different from the repeating unit represented by Formula (4-1).

The molecular chain that contains the repeating unit represented by Formula (4-1) preferably contains 10% by mass to 100% by mass, relative to the total mass of the molecular chain, of the repeating unit represented by Formula (4-1), wherein the percentage is more preferably 40% by mass to 100% by mass.

The hydroxy group depicted in Formula (4-1) may suitably be substituted by the substituent T, or by a group having combined therein the substituent T and a linking group L. A plurality of substituents T, if any, may bond to each other, or may bond to the ring depicted in the formula while being interposed by, or without being interposed by the linking group L, to form a ring.

<<Molecular Chain that Contains Repeating Unit Represented by Formula (5-1)>>

In Formula (5-1), each of R⁵¹ to R⁵⁴ independently represents a hydrogen atom or a substituent, and preferably represents a hydrogen atom from the viewpoint of improving water solubility of the specific resin.

The substituent is preferably represented by the substituent T, which is more preferably alkyl group, more preferably alkyl group having 1 to 4 carbon atoms, and even more preferably methyl group.

The molecular chain that contains the repeating unit represented by Formula (5-1) may further contain a repeating unit which is different from the repeating unit represented by Formula (5-1).

The molecular chain that contains the repeating unit represented by Formula (5-1) preferably contains 10% by mass to 100% by mass, relative to the total mass of the molecular chain, of the repeating unit represented by Formula (5-1), wherein the percentage is more preferably 40% by mass to 100% by mass.

The substituent T is exemplified by alkyl group (whose number of carbon atoms is preferably 1 to 24, more preferably 1 to 12, and even more preferably 1 to 6), arylalkyl group (whose number of carbon atoms is preferably 7 to 21, more preferably 7 to 15, and even more preferably, 7 to 11), alkenyl group (whose number of carbon atoms is preferably 2 to 24, more preferably 2 to 12, and even more preferably, 2 to 6), alkynyl group (whose number of carbon atoms is preferably 2 to 12, more preferably 2 to 6, and even more preferably 2 to 3), hydroxy group, amino group (whose number of carbon atoms is preferably 0 to 24, more preferably 0 to 12, and even more preferably 0 to 6), thiol group, carboxy group, aryl group (whose number of carbon atoms is preferably 6 to 22, more preferably 6 to 18, and even more preferably 6 to 10), alkoxy group (whose number of carbon atoms is preferably 1 to 12, more preferably 1 to 6, and even more preferably 1 to 3), aryloxy group (whose number of carbon atoms is preferably 6 to 22, more preferably 6 to 18, and even more preferably 6 to 10), acyl group (whose number of carbon atoms is preferably 2 to 12, more preferably 2 to 6, and even more preferably 2 to 3), acyloxy group (whose number of carbon atoms is preferably 2 to 12, more preferably 2 to 6, and even more preferably 2 to 3), aryloyl group (whose number of carbon atoms is preferably 7 to 23, more preferably 7 to 19, and even more preferably 7 to 11), aryloyloxy group (whose number of carbon atoms is preferably 7 to 23, more preferably 7 to 19, and even more preferably 7 to 11), carbamoyl group (whose number of carbon atoms is preferably 1 to 12, more preferably 1 to 6, and even more preferably 1 to 3), sulfamoyl group (whose number of carbon atoms is preferably 0 to 12, more preferably 0 to 6, and even more preferably 0 to 3), sulfo group, alkylsulfonyl group (whose number of carbon atoms is preferably 1 to 12, more preferably 1 to 6, and even more preferably 1 to 3), arylsulfonyl group (whose number of carbon atoms is preferably 6 to 22, more preferably 6 to 18, and even more preferably 6 to 10), heterocyclic group (whose number of carbon atoms is preferably 1 to 12, more preferably 1 to 8, and even more preferably 2 to 5, and yet more preferably further contains a five-membered ring or a six-membered ring), (meth)acryloyl group, (meth)acryloyloxy group, halogen atom (for example, fluorine atom, chlorine atom, bromine atom, iodine atom), oxo group (═O), imino group (═NR^{N}), and alkylidene group (═C(R^{N})₂). R^{N} represents a hydrogen atom or alkyl group (whose number of carbon atoms is preferably 1 to 12, more preferably 1 to 6, and even more preferably 1 to 3), among which preferred is hydrogen atom, methyl group, ethyl group, or propyl group. Alkyl moiety, alkenyl moiety and alkynyl moiety contained in the individual substituents may be chain-like or cyclic, and may be straight chain-like or branched. The substituent T, if being a group capable of having a substituent, may further have the substituent T. For example, the alkyl group may be converted to halogenated alkyl group, or to (meth)acryloyloxyalkyl group, amino alkyl group or carboxyalkyl group. The substituent, if being a group capable of forming a salt of carboxy group or amino group, may form a salt.

The linking group L is exemplified by alkylene group (whose number of carbon atoms is preferably 1 to 24, more preferably 1 to 12, and even more preferably 1 to 6), alkenylene group (whose number of carbon atoms is preferably 2 to 12, more preferably 2 to 6, and even more preferably 2 to 3), alkynylene group (whose number of carbon atoms is preferably 2 to 12, more preferably 2 to 6, and even more preferably 2 to 3), (oligo)alkylenoxy group (the number of carbon atoms of alkylene group in one repeating unit is preferably 1 to 12, more preferably 1 to 6, and even more preferably 1 to 3; the number of repetition is preferably 1 to 50, more preferably 1 to 40, and even more preferably 1 to 30), arylene group (whose number of carbon atoms is preferably 6 to 22, more preferably 6 to 18, and even more preferably 6 to 10), oxygen atom, sulfur atom, sulfonyl group, carbonyl group, thiocarbonyl group, —NR^{N}_, and combinations of them. The alkylene group may have the substituent T. For example, the alkylene group may have a hydroxy group. The number of atoms contained in the linking group L, excluding hydrogen atom, is preferably 1 to 50, more preferably 1 to 40, and even more preferably 1 to 30. The number of linking atoms means the number of atoms that reside on the shortest path from among the atomic groups involved in the linkage. In an exemplary case of —CH₂—(C═O)—O—, the number of atoms involved in the linkage is six, and is four after excluding hydrogen atoms. Meanwhile, the shortest path for the linkage is given by —C—C—O—, whose number of atoms is three. The number of linking atoms is preferably 1 to 24, more preferably 1 to 12, and even more preferably 1 to 6. Note that each of the alkylene group, alkenylene group, alkynylene group and (oligo)alkyleneoxy group may be chain-like or cyclic, and may be straight chain-like or branched. The linking group, if being a group capable of forming a salt such as —NR^{N}_, may form a salt.

—Molecular Chain to which Molecular Chain Bonds—

The molecular chain has, bonded to the branched part thereof, a molecular chain having a branched part.

In an exemplary case where the specific resin is a comb-like polymer, a molecular chain having a branched part is understood to be a principal chain, and the molecular chain is understood to be a side chain (grafted chain).

The molecular chain having a branched part, although the structure thereof is not specifically limited, preferably has at least one repeating unit from among repeating units represented by any of Formula (1-1) to Formula (5-1). Preferred embodiments of these repeating units are same as the preferred embodiments of the repeating units represented by any of Formula (1-1) to Formula (5-1) in the aforementioned molecular chain.

The specific resin is preferably a comb-like polymer that has a principal chain that contains at least one repeating unit from among the repeating units represented by any of Formula (1-1) to Formula (5-1), and the branched part; and a side chain that contains at least one repeating unit from among the repeating units represented by Formula (1-1) to Formula (5-1), and bonds to the branched part.

The comb-like polymer is preferably a comb-like polymer that has a principal chain that contains at least one repeating unit from among the repeating units represented by any of Formula (1-1) to Formula (5-1), and, the branched part; and, a side chain that contains at least one repeating unit from among the repeating units represented by Formula (1-1) to Formula (5-1), but different from the repeating unit contained in the principal chain, and bonds to the branched part.

The specific resin, if being a comb-like polymer, is preferably applicable to Embodiment A to Embodiment E below:

Embodiment A: the principal chain contains the repeating unit represented by Formula (1-1), and the side chain contains the repeating unit represented by Formula (2-1);

Embodiment B: the principal chain contains the repeating unit represented by Formula (2-1), and the side chain contains the repeating unit represented by Formula (1-1);

Embodiment C: the principal chain contains the repeating unit represented by Formula (1-1), and the side chain contains the repeating unit represented by Formula (3-1); and

Embodiment D: the principal chain contains the repeating unit represented by Formula (1-1), and the side chain contains the repeating unit represented by Formula (4-1).

Embodiment E: the principal chain contains the repeating unit represented by Formula (5-1), and the side chain contains the repeating unit represented by Formula (1-1).

The specific resin is preferably polyvinyl alcohol-graft-polyvinylpyrrolidone, or, polyethylene glycol-graft-polyvinyl alcohol.

In this patent specification, A-graft-B means a comb-like polymer having A as the principal chain, and B as the side chain (grafted chain). For example, polyvinyl alcohol-graft-polyvinylpyrrolidone has a polyvinyl alcohol chain as the principal chain, and polyvinylpyrrolidone chain as the side chain.

In this patent specification, the polyvinyl alcohol chain means a molecular chain that has the aforementioned repeating unit represented by Formula (1-1), and may be either the aforementioned molecular chain that solely has the repeating unit represented by Formula (1-1), or may be a molecular chain that additionally has other repeating unit. The molecular chain that additionally has other repeating unit is typically exemplified by the molecular chain that has two repeating units represented by Formula (1-2).

In this patent specification, the polyvinylpyrrolidone chain means a molecular chain that has the aforementioned repeating unit represented by Formula (2-1), and may be either the aforementioned molecular chain that solely has the repeating unit represented by Formula (2-1), or may be a molecular chain that additionally has other repeating unit. The molecular chain that additionally has other repeating unit is exemplified by a molecular chain that has two repeating units represented by Formula (2-2).

The specific resin is also preferably a polyvinyl alcohol-graft-polyvinyl alcohol.

The trunk component (principal chain) of the polyvinyl alcohol-graft-polyvinyl alcohol preferably has a degree of polymerization, which may be determined depending on applications of the finally obtainable graft polymer, of 300 or larger, more preferably 500 or larger, and even more preferably 1,000 or larger, meanwhile preferably 10,000 or smaller from the viewpoint of viscosity when solubilized in water. The degree of polymerization herein means viscosity-average degree of polymerization measured conforming to JIS K 6726 (1994). Degree of saponification is preferably 70 to 100 mol %. With the degree of saponification controlled to 70 mol % or larger, the specific resin will have improved water-solubility.

### —Difference of Component Ratio—

Difference between component ratio of the repeating unit in the molecular chain, and the component ratio of the repeating unit in other molecular chain in the resin, is preferably 10 mol % (also denoted as “difference of component ratio is 10 mol %”) or larger, and more preferably 40 mol % to 100 mol %.

The difference of component ratio is defined by the result of subtracting difference(s) of the component ratio(s) of the same repeating unit(s) in two molecular chains, from 100%, and is typically calculated as follows.

Assuming now that the component ratios of repeating units contained in a certain molecular chain are A1 mol % for repeating unit A, B1 mol % for repeating unit B, C1 mol % for repeating unit C, where A1 mol %+B1 mol %+C1 mol %=100 mol %.

Also assuming now that the component ratios of repeating units contained in another molecular chain are A2 mol % for repeating unit A, B2 mol % for repeating unit B, and D2 mol % for repeating unit D, where A2 mol %+B2 mol %+D2 mol %=100 mol %.

The repeating unit A contained in the certain molecular chain and the repeating unit A contained in such another molecular chain are same repeating unit, and, the repeating unit B contained in the certain molecular chain and the repeating unit B contained in such another molecular chain are same repeating unit. The repeating unit C and the repeating unit D are different repeating units.

In this case, difference between the component ratios of the repeating units in the certain molecular chain, and the component ratios of the repeating units in such another molecular chain, is defined to be X mol %. Now, X mol % is a value given by Equation (X) below.

X mol %=100−(|A1−A2|+|B1−B2|) Equation (X):

In the equation, |A1−A2| represents an absolute value of (A1−A2), and |B1−B2| represents an absolute value of (B1−B2).

For the specific resin which is a comb-like polymer, “the component ratio of the repeating unit in a molecular chain, and component ratio of the repeating unit in other molecular chain in the resin” may be “the component ratio of the repeating unit in a certain side chain, and the component ratio of the repeating unit in other side chain”, and is preferably “the component ratio of the repeating unit in a certain side chain, and the component ratio of the repeating unit in the principal chain”.

### —Molecular Weight—

The specific resin preferably has a weight average molecular weight of 10,000 to 1,000,000, which is more preferably 30,000 to 100,000.

The specific resin preferably has a polydispersity (weight average molecular weight/number-average molecular weight) of 1 to 5, which is more preferably 1 to 3.

### Specific Examples

The specific resin are specifically exemplified by, but not limited to, P-1 to P-4 employed later in Examples.

The specific resin may alternatively be any of commercially available products, which include Pitzcol V-7154 (from DKS Co., Ltd., polyvinylpyrrolidone-graft-polyvinyl alcohol), and xanthan gum (from Sansho Co., Ltd., branched polysaccharide, having a structure represented by Formula (3-1) in the principal chain, and having mannose and glucuronic acid in the side chain).

### —Synthetic Methods—

Synthetic methods of the specific resin are exemplified by P-1 to P-4, described later in EXAMPLES.

Moreover, polymers having a variety of grafted chains may be synthesized in the syntheses of P-2 (polyvinyl alcohol-graft-pullulan) or P-3 (polyvinyl alcohol-graft-cellulose), while replacing pullulan or cellulose, with hydroxypropylmethylcellulose, hydroxypropylcellulose, hydroxyethylcellulose, methylcellulose, carboxymethylcellulose, ethylcellulose, cellulose acetate, cellulose acetate phthalate, hydroxypropylcellulose acetate phthalate, hydroxypropylcellulose acetate succinate, hemicellulose, galactomannan, pectin, arginate, carrageenan, xanthane, geranic acid, dextran, curdlan, chitin and derivatives of them; or synthetic polymer such as polyacrylic acid, polymethacrylic acid, copolymer of acrylic ester and methacrylic ester, polyethylene glycol, polyoxyethylene/polyoxypropylene block copolymer, polyvinylpyrrolidone, and derivatives of them.

### —Content—

Content of the specific resin in the protective layer, although suitably adjustable as necessary, is preferably 2% by mass or more, relative to the total mass of the protective layer, more preferably 5% by mass or more, and even more preferably 7% by mass or more. The upper limit value of the content is preferably 100% by mass or below, more preferably 50% by mass or below, and even more preferably 30% by mass or below.

The protective layer may contain only one kind of specific resin, or two or more kinds thereof. When two or more kinds are contained, the total content falls within the aforementioned ranges.

The protective layer may further contain other resin different from the aforementioned resin.

Such other resin is preferably a water-soluble resin.

The water-soluble resin preferably contains a hydrophilic group, and the hydrophilic group is exemplified by hydroxy group, carboxy group, sulfonic acid group, phosphoric acid group, amido group and imido group.

The water-soluble resin is specifically exemplified by polyvinylpyrrolidone (PVP), polyvinyl alcohol (PVA), water-soluble polysaccharides {water-soluble celluloses (methylcellulose, hydroxyethylcellulose, hydroxypropylcellulose, hydroxyethylmethylcellulose, hydroxypropylmethylcellulose, etc.), pullulan or pullulan derivative, starch, hydroxypropyl starch, carboxymethylstarch, chitosan, and cyclodextrin}, polyethylene oxide, and polyethyloxazoline. Two or more kinds of these water-soluble resins may be selected for use, or may be used as a copolymer.

Among these resins, the protective layer in this invention preferably contain at least one selected from the group consisting of polyvinylpyrrolidone, polyvinyl alcohol, water-soluble polysaccharide, pullulan and pullulan derivative.

More specifically in this invention, the water-soluble resin contained in the protective layer is preferably a resin that contains a repeating unit represented by any one of Formula (P1-1) to Formula (P4-1).

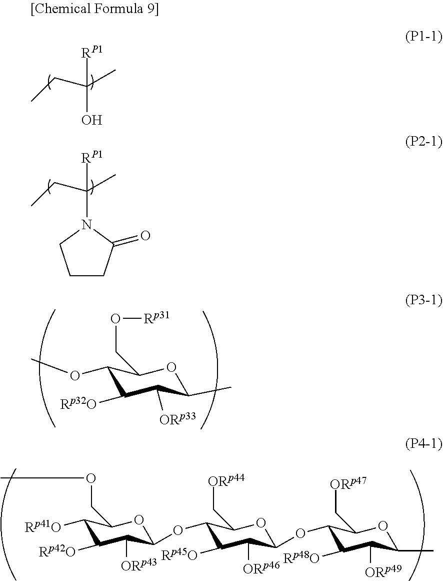

In Formulae (P1-1) to (P4-1), R^{P1} represents a hydrogen atom or a methyl group, R^{P2} represents a hydrogen atom or a methyl group, each of R^{p31} to R^{p33} independently represents a substituent or a hydrogen atom, and each of R^{p41} to R^{p49} independently represents a substituent or a hydrogen atom.

[Resin that Contains Repeating Unit Represented by Formula (P1-1)]

In Formula (P1-1), R^{P1} preferably represents hydrogen atom.

The resin that contains the repeating unit represented by Formula (P1-1) may further contain a repeating unit different from the repeating unit represented by Formula (P1-1).

The resin that contains the repeating unit represented by Formula (P1-1) preferably contains 10% by mass to 100% by mass of the repeating unit represented by Formula (P1-1), relative to the total mass of the resin, and the content is more preferably 30% by mass to 70% by mass.

The resin that contains the repeating unit represented by Formula (P1-1) is exemplified by a resin that contains two kinds of repeating unit represented by Formula (P1-2) below.

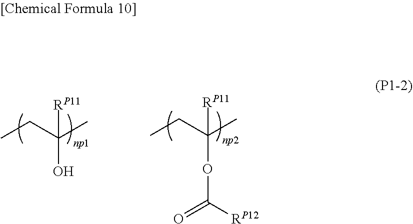

In Formula (P1-2), each R^{P11} independently represents a hydrogen atom or a methyl group, R^{P12} represents a substituent, and each of np1 and np2 represents component ratio, on the mass basis, in the molecule.

In Formula (P1-2), R^{P11} is synonymous to R^{P1} in Formula (P1-1), whose preferred embodiments are also same.

In Formula (P1-2), R^{P12} is exemplified by a group represented by -L^{P}-T^{P}. L^{P} represents a single bond of a linking group L described later. T^{P} represents a substituent, and is exemplified by substituent T described later. In particular, R^{P12} preferably represents any of hydrocarbon groups exemplified by alkyl group (whose number of carbon atoms is preferably 1 to 12, more preferably 1 to 6, and even more preferably 1 to 3), alkenyl group (whose number of carbon atoms is preferably 2 to 12, more preferably 2 to 6, and even more preferably 2 or 3), alkynyl group (whose number of carbon atoms is preferably 2 to 12, more preferably 2 to 6, and even more preferably 2 to 3), aryl group (whose number of carbon atoms is preferably 6 to 22, more preferably 6 to 18, and even more preferably 6 to 10), and arylalkyl group (whose number of carbon atoms is preferably 7 to 23, more preferably 7 to 19, and even more preferably 7 to 11). These alkyl group, alkenyl group, alkynyl group, aryl group, and arylalkyl group may further have a group specified by substituent T, so far as the effect of this invention may be demonstrated.

In Formula (P1-2), each of np1 and np2 represents component ratios, on the mass basis, in the molecule, and is independently 10% by mass or larger and smaller than 100% by mass. Note, however, (np1+np2) never exceeds 100% by mass. With (np1+np2) fallen under 100% by mass, such resin means a copolymer that contains the other repeating unit.

[Resin that Contains Repeating Unit Represented by Formula (P2-1)]

In Formula (P2-1), R^{P2} preferably represents a hydrogen atom.

The resin that contains the repeating unit represented by Formula (P2-1) may further contain a repeating unit different from the repeating unit represented by Formula (P2-1).

The resin that contains the repeating unit represented by Formula (P2-1) preferably contains 10% by mass to 100% by mass of the repeating unit represented by Formula (P2-1), relative to the total mass of the resin, wherein the content is more preferably 30% by mass to 70% by mass.

The resin that contains the repeating unit represented by Formula (P2-1) is exemplified by a resin that contains two kinds of repeating unit represented by Formula (P2-2) below.

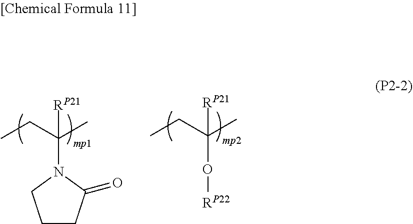

In Formula (P2-2), each R^{P21} independently represents a hydrogen atom or a methyl group, R^{P22} represents a substituent, and each of mp1 and mp2 represents component ratio, on the mass basis, in the molecule.

In Formula (P2-2), R^{P21} is synonymous to R^{P2} in Formula (P2-1), whose preferred embodiments are also same.

In Formula (P2-2), R^{P22} is exemplified by a group represented by -L^{P}-T^{P}. L^{P} represents a single bond or a linking group L described later. T^{P} is a substituent, and is exemplified by substituent T described later. In particular, R^{P22} is preferably any of hydrocarbon groups exemplified by alkyl group (whose number of carbon atoms is preferably 1 to 12, more preferably 1 to 6, and even more preferably 1 to 3), alkenyl group (whose number of carbon atoms is preferably 2 to 12, more preferably 2 to 6, and even more preferably 2 to 3), alkynyl group (whose number of carbon atoms is preferably 2 to 12, more preferably 2 to 6, and even more preferably 2 to 3), aryl group (whose number of carbon atoms is preferably 6 to 22, more preferably 6 to 18, and even more preferably 6 to 10), or arylalkyl group (whose number of carbon atoms is preferably 7 to 23, more preferably 7 to 19, and even more preferably 7 to 11). These alkyl group, alkenyl group, alkynyl group, aryl group, and arylalkyl group may further have a group specified by substituent T, so far as the effect of this invention may be demonstrated.

In Formula (P2-2), each of mp1 and mp2 represents component ratio, on the mass basis, in the molecule, and is independently 10% by mass or larger and smaller than 100% by mass. Note, however, (mp1+mp2) never exceeds 100% by mass. With (mp1+mp2) fallen under 100% by mass, such resin means a copolymer that contains the other repeating unit.

[Resin that Contains Repeating Unit Represented by Formula (P3-1)]

In Formula (P3-1), each of R^{p31} to R^{p33} independently and preferably represents an optionally substituted hydrocarbon group, acyl group, —(CH₂CH₂O)ₘₐH, —CH₂COONa or hydrogen atom, more preferably represents a hydrocarbon group, hydrocarbon group having hydroxy group as a substituent, acyl group or hydrogen atom, and even more preferably represents a hydrogen atom. ma Represents 1 or 2.

The optionally substituted hydrocarbon group preferably has 1 to 10 carbon atoms, and more preferably has 1 to 4 carbon atoms.

The hydrocarbon group having hydroxy group as a substituent is preferably a hydrocarbon group having hydroxy group and 1 to 10 carbon atoms, more preferably a hydrocarbon group having one hydroxy group and 1 to 4 carbon atoms, and even more preferably —CH₂(OH), —CH₂CH₂(OH) or —CH₂CH(OH)CH₃.

The acyl group is preferably an alkylcarbonyl group whose alkyl group has 1 to 4 carbon atoms, and more preferably acetyl group.

The resin that contains the repeating unit represented by Formula (P3-1) may contain a repeating unit different from the repeating unit represented by Formula (P3-1).

The resin that contains the repeating unit represented by Formula (P3-1) preferably contains 10% by mass to 100% by mass of the repeating unit represented by Formula (P3-1), relative to the total mass of the resin, and the content is more preferably 30% by mass to 70% by mass.

The hydroxy group denoted in Formula (P3-1) may suitably be substituted by the substituent T or by a group combining the substituent T with a linking group L. In a case where there are a plurality of substituents T, they may bind to each other, or may bind to the ring in the formula while being interposed by, or without being interposed by the linking group L below, to form a ring.

[Resin that Contains Repeating Unit Represented by Formula (P4-1)]

In Formula (P4-1), each of R^{P41} to R^{P49} independently represents an optionally substituted hydrocarbon group, acyl group, —(CH₂CH₂O)ₘₐH, —CH₂COONa or hydrogen atom, more preferably represents a hydrocarbon group, hydrocarbon group having hydroxy group as a substituent, acyl group or hydrogen atom, and even more preferably represents a hydrogen atom. ma Represents 1 or 2.

The optionally substituted hydrocarbon group preferably has 1 to 10 carbon atoms, and more preferably has 1 to 4 carbon atoms.

The hydrocarbon group having hydroxy group as a substituent is preferably a hydrocarbon group having one hydroxy group and 1 to 10 carbon atoms, more preferably a hydrocarbon group having one hydroxy group and 1 to 4 carbon atoms, and even more preferably —CH₂(OH), —CH₂CH₂(OH) or —CH₂CH(OH)CH₃.

The resin that contains the repeating unit represented by Formula (P4-1) may further contain a repeating unit different from the repeating unit represented by Formula (P4-1).

The resin that contains the repeating unit represented by Formula (P4-1) preferably contains 10% by mass to 100% by mass of the repeating unit represented by Formula (P4-1), relative to the total mass of the resin, and the content is more preferably 30% by mass to 70% by mass.

The hydroxy group denoted in Formula (P4-1) may suitably be substituted by the substituent T or by a group combining the substituent T with a linking group L. In a case where there are a plurality of substituents T, they may bind to each other, or may bind to the ring in the formula while being interposed by, or without being interposed by the linking group L below, to form a ring.

Other examples of the water-soluble resin include polyethylene oxide, hydroxyethylcellulose, carboxymethylcellulose, water-soluble methylolmelamine, polyacrylamide, phenol resin, styrene/maleic hemiester, and poly(N-vinylacetamide).

The water-soluble resin is also commercially available, wherein marketed products include Pitzcol Series (K-30, K-50, K-90, etc.) from DKS Co., Ltd.; LUVITEC Series (VA64P, VA6535P, etc.) from BASF, SE.; PXP-05, JL-05E, JP-03, JP-04 and AMPS (2-acrylamido-2-metylpropanesulfonic acid copolymer); and Nanoclay from Aldrich.

Among them, Pitzcol K-90 or PXP-05 is preferably used.

Regarding the water-soluble resin, the resins described in WO2016/175220 may be referred to, which is incorporated by reference into this patent specification.

Weight-average molecular weight of the water-soluble resin is preferably 50,000 to 400,000 for polyvinylpyrrolidone, preferably 15,000 to 100,000 for polyvinyl alcohol, and preferably 10,000 to 300,000 for other resins.

The water-soluble resin used in this invention preferably has a polydispersity (weight-average molecular weight/number-average molecular weight) of 1.0 to 5.0, which is more preferably 2.0 to 4.0.

In a case where the protective layer contains other resin, content of such other resin in the protective layer may suitably be adjusted as necessary, and is preferably 30% by mass or less, relative to the total mass of the protective layer, more preferably 25% by mass or less, and even more preferably 20% by mass. The lower limit is preferably 1% by mass or above, more preferably 2% by mass or above, and even more preferably 4% by mass or above.

In a case where the protective layer contains other resin, content of such other resin in the protective layer is preferably 1 to 99% by mass, relative to the total mass of the specific resin, and more preferably 10 to 90% by mass.

The protective layer may contain only one kind of other resin, or two or more kinds thereof. When two or more kinds are contained, the total content preferably falls within the aforementioned ranges.

### [Surfactant Having Acetylene Group]

From the viewpoint of suppressing residue from producing, the protective layer preferably contains a surfactant having acetylene group.

The number of acetylene groups in the molecule of the surfactant having acetylene group is preferably 1 to 10, more preferably 1 to 5, even more preferably 1 to 3, and yet more preferably 1 to 2, although not specifically limited.

Relatively small molecular weight is preferred for the surfactant having acetylene group, which is preferably 2,000 or smaller, more preferably 1,500 or smaller, and even more preferably 1,000 or smaller. The lower limit value is preferably 200 or above, although not specifically limited.

### —Compound Represented by Formula (9)—

The surfactant having acetylene group is preferably a compound represented by Formula (9) below.

[Chemical Formula 12]

R⁹¹—C≡C—R⁹² (9)

In formula each of R⁹¹ and R⁹² independently represents an alkyl group having 3 to 15 carbon atoms, aromatic hydrocarbon group having 6 to 15 carbon atoms, or, aromatic heterocyclic group having 4 to 15 carbon atoms. The number of carbon atoms of the aromatic heterocyclic group is preferably 1 to 12, more preferably 2 to 6, and even more preferably 2 to 4. The aromatic heterocycle is preferably a five-membered ring or six-membered ring. The heteroatom contained in the aromatic heterocycle is preferably a nitrogen atom, oxygen atom, or sulfur atom.

Each of R⁹¹ and R⁹² may independently have a substituent which is exemplified by the aforementioned substituents.

### —Compound Represented by Formula (91)—

A compound represented by Formula (9) is preferably represented by Formula (91) below.

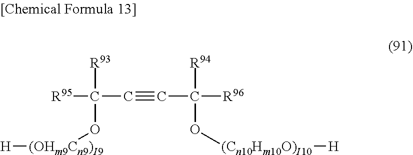

Each of R⁹³ to R⁹⁶ independently represents a hydrocarbon group having 1 to 24 carbon atoms, n9 represents an integer of 1 to 6, m9 represents an integer twice as large as n9, n10 represents an integer of 1 to 6, m10 represents an integer twice as large as n10, and each of 19 and 110 independently represents the number of 0 or larger and 12 or smaller.

Each of R⁹³ to R⁹⁶ represents any of hydrocarbon groups, among which preferred are alkyl group (whose number of carbon atoms is preferably 1 to 12, more preferably 1 to 6, and even more preferably 1 to 3), alkenyl group (whose number of carbon atoms is preferably 2 to 12, more preferably 2 to 6, and even more preferably 2 to 3), alkynyl group (whose number of carbon atoms is preferably 2 to 12, more preferably 2 to 6, and even more preferably 2 to 3), aryl group (whose number of carbon atoms is preferably 6 to 22, more preferably 6 to 18, and even more preferably 6 to 10), or arylalkyl group (whose number of carbon atoms is preferably 7 to 23, more preferably 7 to 19, and even more preferably 7 to 11). The alkyl group, the alkenyl group, and the alkynyl group may be chain-like or cyclic, and may be straight chain-like or branched. Each of R⁹³ to R⁹⁶ may have a substituent T so far as the effect of this invention may be demonstrated. Any of R⁹³ to R⁹⁶ may bind to each other directly or while being interposed by the aforementioned linking group L, to form a ring. In a case where there are a plurality of substituents T, they may bind to each other, or may bind to the hydrocarbon group in the formula while being interposed by, or without being interposed by the linking group L below, to form a ring.

Each of R⁹³ and R⁹⁴ preferably represents any of alkyl groups (whose number of carbon atoms is preferably 1 to 12, more preferably 1 to 6, and even more preferably 1 to 3). Among them, methyl group is preferred.

Each of R⁹⁵ and R⁹⁶ preferably represents any of alkyl groups (whose number of carbon atoms is preferably 1 to 12, more preferably 2 to 6, and even more preferably 3 to 6). Among which, —(Cₙ₁₁R⁹⁸ₙ₁₁)—R⁹⁷ is preferred. Each of R⁹⁵ and R⁹⁶ particularly preferably represents isobutyl group.

n11 Represents an integer of 1 to 6, and preferably an integer of 1 to 3. m11 Represents a number twice as large as n11.

Each of R⁹⁷ and R⁹⁸ independently represents a hydrogen atom or an alkyl group (whose number of carbon atoms is preferably 1 to 12, more preferably 1 to 6, and even more preferably 1 to 3).

n9 Represents an integer of 1 to 6, and preferably an integer of 1 to 3. m9 Represents a number twice as large as n9.

n10 Represents an integer of 1 to 6, and preferably an integer of 1 to 3. m10 Represents a number twice as large as n10.

Each of 19 and 110 independently represents an integer of 0 to 12, where the number (19+110) is preferably 0 to 12, more preferably 0 to 8, and even more preferably 0 to 6, yet more preferably exceeding 0 and smaller than 6, and furthermore preferably exceeding 0 and 3 or smaller. Note that the compound represented by Formula (91) may occasionally be a mixture of compounds having different number for 19 and 110, so that each of 19 and 110, or (19+110) may have a value below a decimal point.

### —Compound Represented by Formula (92)—

A compound represented by Formula (91) is preferably a compound represented by Formula (92) below.

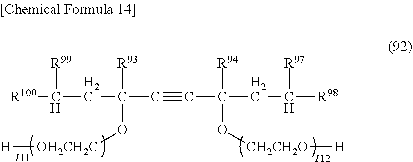

Each of R⁹³, R⁹⁴, R⁹⁷ to R¹⁰⁰ independently represents a hydrocarbon group having 1 to 24 carbon atoms, and each of 111 and 112 independently represents the number of 0 or larger and 12 or smaller.

Among them, each of R⁹³, R⁹⁴, R⁹⁷ to R¹⁰⁰ preferably represents an alkyl group (whose number of carbon atoms is preferably 1 to 12, more preferably 1 to 6, and even more preferably 1 to 3), an alkenyl group (whose number of carbon atoms is preferably 2 to 12, more preferably 2 to 6, and even more preferably 2 to 3), an alkynyl group (whose number of carbon atoms is preferably 2 to 12, more preferably 2 to 6, and even more preferably 2 to 3), an aryl group (whose number of carbon atoms is preferably 6 to 22, more preferably 6 to 18, and even more preferably 6 to 10), or an arylalkyl group (whose number of carbon atoms is preferably 7 to 23, more preferably 7 to 19, and even more preferably 7 to 11). Each of the alkyl group, alkenyl group, and alkynyl group may be chain-like or cyclic, and may be straight chain-like or branched. Each of R⁹³, R⁹⁴, R⁹⁷ to R¹⁰⁰ may have a substituent T so far as the effect of this invention may be demonstrated. Each of R⁹³, R⁹⁴, R⁹⁷ to R¹⁰⁰ may bind to each other directly or while being interposed by the linking group L, to form a ring. In a case where there are a plurality of substituents T, they may bind to each other, or may bind to the hydrocarbon group in the formula while being interposed by, or without being interposed by the linking group L below, to form a ring.

Each of R⁹³, R⁹⁴, R⁹⁷ to R¹⁰⁰ independently and preferably represents any of alkyl groups (whose number of carbon atoms is preferably 1 to 12, more preferably 1 to 6, and even more preferably 1 to 3). Among then, methyl group is preferred.

(111+112) Preferably has the number of 0 to 12, which is more preferably 0 to 8, even more preferably 0 to 6, yet more preferably exceeding 0 and smaller than 6, furthermore preferably exceeding 0 and 5 or smaller, furthermore preferably exceeding 0 and 4 or smaller, may be the number exceeding 0 and 3 or smaller, and also may be the number exceeding 0 and 1 or smaller. Note that the compound represented by Formula (92) may occasionally be a mixture of compounds having different numbers for 111 and 112, so that each of 111 and 112, or (111+112) may have a value below a decimal point.

The surfactant that contains acetylene group is exemplified by Surfynol 104 Series (trade name, from Nisshin Chemical Co., Ltd.), and Acetylenol E00, ibid. E40, ibid. E13T, ibid. 60 (all trade names, from Kawaken Fine Chemicals Co., Ltd.), among which, Surfynol 104 Series, and Acetylenol E00, ibid. E40, ibid. E13T are more preferred, and Acetylenol E40, ibid. E13T are even more preferred. Note that Surfynol 104 Series and Acetylenol E00 are surfactants having the same structure.

### [Other Surfactants]

The protective layer may further contain other surfactants, besides the surfactant that contains acetylene group, typically for the purpose of improving coatability of the protective layer forming composition described later.

The other surfactants may only be capable of reducing surface tension, and may be freely selectable from nonionic, anionic, and amphoteric fluorine-containing ones.

Usable examples of the other surfactants include nonionic surfactants that include polyoxyethylene alkyl ethers such as polyoxyethylene lauryl ether, polyoxyethylene cetyl ether and polyoxyethylene stearyl ether, polyoxyethylenealkylaryl ethers such as polyoxyethylene octyl phenyl ether and polyoxyethylene nonyl phenyl ether, polyoxyethylene alkyl esters such as polyoxyethylene stearate, sorbitan alkyl esters such as sorbitan monolaurate, sorbitan monostearate, sorbitan distearate, sorbitan monooleate, sorbitan sesquioleate, and sorbitan trioleate, monoglyceride alkyl esters such as glycerol monostearate, and glycerol monooleate, and fluorine- or silicon-containing oligomers; anionic surfactants that include alkylbenzenesulfonates such as sodium dodecylbenzenesulfonate, alkylnaphthalenesulfonates such as sodium butylnaphthalenesulfonate, sodium pentylnaphthalenesulfonate, sodium hexylnaphthalenesulfonate and sodium octylnaphthalenesulfonate, alkyl sulfates such as sodium laurylsulfate, alkylsulfonates such as sodium dodecylsulfonate, and sulfosuccinate ester salts such as sodium dilaurylsulfosuccinate; alkyl betaines such as lauryl betaine and stearyl betaine, and, amphoteric surfactants such as amino acids.

For the protective layer that contains the surfactant that contains acetylene group and the other surfactant, the amount of addition of the surfactants, in terms of total amount of the surfactant that contains acetylene group and the other surfactant, relative to the total mass of the protective layer, is preferably 0.05 to 20% by mass, more preferably 0.07 to 15% by mass, and even more preferably 0.1 to 10% by mass. Only one kind, or two or more kinds of these surfactants may be used. When two or more kinds are used, the total content falls within the aforementioned ranges.

Alternatively, this invention may be substantially free of such other surfactant. “Substantially free of . . . ” means that the content of the other surfactant is 5% by mass or less of the content of the surfactant that contains acetylene group, and is preferably 3% by mass or less, and more preferably 1% by mass or less.

Content of the surfactant in the protective layer is preferably 0.05% by mass or more, relative to the total mass of the protective layer, more preferably 0.07% by mass more, and even more preferably 0.1% by mass or more. The upper limit value is preferably 20% by mass or below, more preferably 15% by mass or below, and even more preferably 10% by mass below. Only one kind, or two or more kinds of the other surfactant may be used. When two or more kinds are used, the total content falls within the aforementioned ranges.

The other surfactant, in the form of a 0.1% by mass aqueous solution, preferably has a surface tension at 23° C. of 45 mN/m or smaller, which is more preferably, 40 mN/m or smaller, and even more preferably 35 mN/m or smaller. The lower limit value is preferably 5 mN/m or above, more preferably 10 mN/m or above, and even more preferably 15 mN/m or above. The surface tension of the surfactant may only be properly selected depending on types of the surfactant to be chosen.

### [Preservative and Fungicide (Preservatives, Etc.)]

Another preferred embodiment is that the protective layer contains a preservative or fungicide.

The preservative and fungicide (referred to as “preservatives, etc.”, hereinafter) are additives having antibacterial or antifungal effect, and preferably contain at least either compound selected from water-soluble or water-dispersible organic compounds. The additive having antibacterial or antifungal effect, such as the preservatives, etc. is exemplified by organic antibacterial agent or fungicide, inorganic antibacterial agent or fungicide, and naturally-occurring antibacterial agent or fungicide. The antibacterial or fungicide applicable here may be those described, for example, in “Kokin Boukabi Gijyutu” (in Japanese, “Antibacterial and Antifungal Technologies”), published by Toray Research Center, Inc.

In this invention, addition of the preservatives, etc. to the protective layer more successfully enables an effect of suppressing coating defect, due to bacterial proliferation in the solution after long-term storage at room temperature, from increasing.

The preservatives, etc. is exemplified by phenol ether compounds, imidazol compounds, sulfone compounds, N-haloalkylthio compound, anilide compounds, pyrrole compounds, quaternary ammonium salt, arsine compounds, pyridine compounds, triazine compounds, benzoisothiazoline compounds, and isothiazoline compounds. Specific examples include 2-(4-thiocyanomethyl)benzimidazol, 1,2-benzothiazolone, 1,2-benzisothiazoline-3-one, N-fluorodichloromethylthio-phthalimide, 2,3,5,6-tetrachloroisophthalonitrile, N-trichloromethylthio-4-cyclohexene-1,2-dicarboxyimide, copper 8-quinolinate, bis(tributyltin) oxide, 2-(4-thiazolyl)benzimidazol, methyl 2-benzimidazolcarbamate, 10,10′-oxybisphenoxyarsine, 2,3,5,6-tetrachloro-4-(methylsulfone)pyridine, zinc bis(2-pyridylthio-1-oxide), N,N-dimethyl-N′-(fluorodichloromethylthio)-N′-phenylsulfamide, poly(hexamethylene biguanide) hydrochloride, dithio-2,2′-bis-2-methyl-4,5-trimethylene-4-isothiazoline-3-one, 2-bromo-2-nitro-1,3-propanediol, hexahydro-1,3-tris(2-hydroxyethyl)-S-triazine, p-chloro-m-xylenol, 1,2-benzisothiazoline-3-one, and methylphenol.

The naturally-occurring antibacterial agent or fungicide is exemplified by chitosan, which is a basic polysaccharide obtained by hydrolyzing chitin typically contained in shell of crab or shrimp. A preferred example is “Holonkiller bead SERA”, which is composed of “amino metal” having an amino acid complexed with metal at both ends.

Content of the preservatives, etc. in the protective layer is preferably 0.005 to 5% by mass, relative to the total mass of the protective layer, more preferably 0.01 to 3% by mass, even more preferably 0.05 to 2% by mass, and yet more preferably 0.1 to 1% by mass. Only one kind, or two or more kinds of the preservatives, etc. may be used. When two or more kinds are used, the total content falls within the aforementioned ranges.

Antibacterial effect of the preservatives, etc. may be evaluated in compliance with JIS Z 2801 (Antibacterial products—Test for antibacterial activity and efficacy). Antifungal effect may be evaluated in compliance with JIS Z 2911 (Methods of test for fungus resistance).

### [Light Shield Agent]

The protective layer preferably contains a light shield agent. Addition of the light shield agent can further suppress the organic layer and so forth from being damaged by light.

The light shield agent usable here may be any of known colorants or the like, and is exemplified by organic or inorganic pigment or dye, preferably exemplified by inorganic pigment, and more preferably by carbon black, titanium oxide, and titanium nitride.

Content of the light shield agent is preferably 1 to 50% by mass, relative to the total mass of the, protective layer, more preferably 3 to 40% by mass, and even more preferably 5 to 25% by mass. Only one kind, or two or more kinds of light shield agent may be used. When two or more kinds are used, the total content falls within the aforementioned ranges.

### [Thickness]

The protective layer preferably has a thickness of 0.1 μm or larger, which is more preferably 0.5 μm or larger, even more preferably 1.0 μm or larger, and yet more preferably, 2.0 μm or larger. The upper limit value of the thickness of the protective layer is preferably 10 μm or below, more preferably 5.0 μm or below, and even more preferably 3.0 μm or below.

### [Stripping Solution]

The protective layer in this invention is subjected to stripping with use of a stripping solution.

Method for stripping of the protective layer with use of the stripping solution will be described later.

The stripping solution is preferably water, mixture of water and water-soluble solvent, and water-soluble solvent, among which preferred is water, or mixture of water and water-soluble solvent.

Content of water, relative to the total mass of the stripping solution is preferably 90 to 100% by mass, and more preferably 95 to 100% by mass. The stripping solution may alternatively be a stripping solution solely containing water.

In this patent specification, water, mixture of water and water-soluble solvent, and, water-soluble solvent may occasionally and collectively be referred to as “aqueous solvent”.

The water-soluble solvent is preferably an organic solvent having a solubility in water at 23° C. of 1 g or larger, more preferably an organic solvent having a solubility of 10 g or larger, and even more preferably an organic solvent having a solubility of 30 g or larger.

The water-soluble solvent is exemplified by alcohol solvents such as methanol, ethanol, propanol, ethylene glycol, and glycerin; ketone solvents such as acetone; and amide solvent such as formamide.

The stripping solution may contain a surfactant, for the purpose of improving strippability of the protective layer.

The surfactant usable here may be any of known compounds, and is preferably exemplified by nonionic surfactant.

### [Protective Layer Forming Composition]

The protective layer forming composition of this invention contains the specific resin, and is used for forming the protective layer contained in the laminate.

In the laminate of this invention, the protective layer may be formed typically by applying the protective layer forming composition over the organic layer, and then by allowing it to dry.

The protective layer forming composition is preferably applied by coating. Method of application is exemplified by slit coating, casting, blade coating, wire bar coating, spray coating, dipping (immersion) coating, bead coating, air knife coating, curtain coating, ink jet method, spin coating, and Langmuir-Blodgett (LB) method, wherein more preferred are casting, spin coating, and ink jet method. Such processes enable low-cost production of the protective layer with a smooth surface and a large area.

The protective layer may alternatively be formed by applying the protective layer forming composition over a tentative support by the aforementioned method of application to preliminarily form a coated film, and then by transferring the coated film onto a target of application (the organic layer, for example).

Regarding the method of transfer, the descriptions in paragraphs [0023], [0036] to [0051] of JP-2006-023696 A, and in paragraphs [0096] to [0108] of JP-2006-047592 A may be referred to.

The protective layer forming composition preferably contains the component contained in the aforementioned protective layer (for example, water-soluble resin, surfactant that contains acetylene group, other surfactant, preservative, light shield agent, etc.), and a solvent.

Regarding the content of the components contained in the protective layer forming composition, the contents of the aforementioned individual components relative to the total mass of the protective layer are preferably deemed to be the contents relative to the total solid content of the protective layer forming composition.

The solvent contained in the protective layer forming composition is exemplified by the aforementioned aqueous solvent, which is preferably water or mixture of water and water-soluble solvent, and is more preferably water.

The aqueous solvent, when being a mixed solvent, is preferably a mixed solvent of water and an organic solvent, having a solubility at 23° C. into water of 1 g or larger. The solubility of the organic solvent at 23° C. into water is more preferably 10 g or larger, and even more preferably 30 g or larger.

Solid concentration of the protective layer forming composition is preferably 0.5 to 30% by mass, from the viewpoint of easiness of application of the protective layer forming composition so as to achieve a nearly uniform thickness, and is more preferably 1.0 to 20% by mass, and even more preferably 2.0 to 14% by mass.

### <Photo-Sensitive Layer>

The laminate of this invention contains a photo-sensitive layer.

In this invention, the photo-sensitive layer is a layer intended for development with use of a developing solution.

The development is preferably of negative type.

To the photo-sensitive layer, any of photo-sensitive layer (for example, photoresist layer) known in this technical field is suitably applicable.

In the laminate of this invention, the photo-sensitive layer may be a negative photo-sensitive layer, or may be a positive photo-sensitive layer.

The photo-sensitive layer is preferably such that a light exposed area thereof turns less soluble in the developing solution that contains an organic solvent. “Less soluble” means that the light exposed area is less likely to dissolve into a developing solution.

The dissolution rate of the light exposed area of the photo-sensitive layer into the developing solution preferably becomes smaller (becomes less soluble) than the dissolution rate of the unexposed area of the photo-sensitive layer into the developing solution.

More specifically, the photo-sensitive layer preferably changes the polarity upon light exposure at least at a wavelength of 365 nm (i-line), 248 nm (KrF laser) of 193 nm (ArF laser), under an irradiation dose of 50 mJ/cm² or larger, and becomes less soluble into a solvent having an sp value (solubility parameter) of smaller than 19.0 (MPa)^{1/2}, more preferably into a solvent having an sp value of 18.5 (MPa)^{1/2} or smaller, and even more preferably into a solvent having an sp value of 18.0 (MPa)^{1/2} or smaller.

In this invention, the solubility parameter (sp value) [in (MPa)^{1/2}] is determined by the Okitsu method. The Okitsu method is one of known methods of estimating the sp value, and is detailed for example in Journal of the Adhesion Society of Japan, Vol. 29, No. 6 (1993) p. 249-259.

In addition, the photo-sensitive layer preferably changes the polarity as described above, upon being exposed at least at one wavelength selected from 365 nm (i-line), 248 nm (KrF laser) and 193 nm (ArF laser) under an irradiation dose of 50 to 250 mJ/cm².

The photo-sensitive layer preferably demonstrates photo-sensitivity to irradiation with i-line.

The photo-sensitivity means capability of changing the dissolution rate into an organic solvent (preferably, butyl acetate), upon being irradiated by at least either active ray or radiation beam (irradiation with i-line, for the photo-sensitivity aimed at i-line).

The photo-sensitive layer is exemplified by a photo-sensitive layer that contains a resin whose dissolution rate into the developing solution can change in response to action of an acid (also referred to as “photo-sensitive layer forming specific resin”, hereinafter).

The change in the dissolution rate of the photo-sensitive layer forming specific resin is preferably slowing down of the dissolution rate.

The dissolution rate of the photo-sensitive layer forming specific resin, before causing change, into an organic solvent with an sp value of 18.0 (MPa)^{1/2} or smaller, is more preferably 40 nm/sec or faster.

The dissolution rate of the photo-sensitive layer forming specific resin, after causing change, into an organic solvent with an sp value of 18.0 (MPa)^{1/2} or smaller, is more preferably slower than 1 nm/sec.

The photo-sensitive layer forming specific resin is preferably soluble in an organic solvent with an sp value (solubility parameter) of 18.0 (MPa)^{1/2} or smaller before causing change in the dissolution rate, and, is preferably less soluble in an organic solvent with an sp value of 18.0 (MPa)^{1/2} or smaller after causing change in the dissolution rate.

Now “soluble in an organic solvent with an sp value (solubility parameter) of 18.0 (MPa)^{1/2} or smaller” means that the compound (resin), when coated on a base, heated at 100° C. for one minute to be formed into coated film (1 μm thick), and immersed in a developing solution at 23° C., demonstrates a dissolution rate of 20 nm/sec or faster. Meanwhile, “less soluble in an organic solvent with an sp value of 18.0 (MPa)^{1/2} or smaller” means that the compound (resin), when coated on a base, heated at 100° C. for one minute to be formed into coated film (1 μm thick), and immersed in a developing solution at 23° C., demonstrates a dissolution rate of slower than 10 nm/sec.

The photo-sensitive layer is exemplified by a photo-sensitive layer that contains the photo-sensitive layer forming specific resin and a photo-acid generator; and a photo-sensitive layer that contains the polymerizable compound, a photo-polymerization initiator and so forth.

The photo-sensitive layer is preferably a chemical amplification type photo-sensitive layer, from the viewpoint of excellent shelf stability and fine patternability.

Examples of the photo-sensitive layer that contains the photo-sensitive layer forming specific resin and a photo-acid generator will be explained.

### [Photo-Sensitive Layer Forming Specific Resin]

The photo-sensitive layer in this invention preferably contains a photo-sensitive layer forming specific resin.

The photo-sensitive layer forming specific resin is preferably an acrylic polymer.

The “acrylic polymer” is an addition-polymerized resin, contains a repeating unit derived from (meth)acrylic acid or ester thereof, and may also contain a repeating unit other than (meth)acrylic acid or esters thereof, for example, may also contain a repeating unit derived from styrenes or a repeating unit derived from vinyl compound. The acrylic polymer preferably contains 50 mol % or more of the repeating unit derived from (meth)acrylic acid or ester thereof, relative to the total repeating unit in the polymer, the content is more preferably 80 mol % or more. The acrylic polymer is particularly preferably a polymer solely composed of the repeating units derived from (meth)acrylic acid and ester thereof.

The photo-sensitive layer forming specific resin is preferably exemplified by a resin having a repeating unit whose acid group is protected with an acid-decomposable group.

The structure whose acid group is protected by an acid-decomposable group is exemplified by a structure whose carboxy group is protected by an acid-decomposable group, and a structure whose phenolic hydroxy group is protected by an acid-decomposable group.

The repeating unit having a structure whose acid group is protected by an acid-decomposable group is exemplified by a repeating unit whose carboxy group in a monomer unit, derived from (meth)acrylic acid, is protected by an acid-decomposable group; and a repeating unit whose phenolic hydroxy group in a monomer unit, derived from hydroxystyrenes such as p-hydroxystyrene or α-methyl-p-hydroxystyrene, is protected by an acid-decomposable group.

The repeating unit having a structure whose acid group is protected by an acid-decomposable group is exemplified by a repeating unit that contains an acetal structure, and is preferably a repeating unit having a cyclic ether ester structure in the side chain. The cyclic ether ester structure preferably forms the acetal structure in which an oxygen atom in the cyclic ether structure and an oxygen atom in the ester bond are bound on the same carbon atom.

The repeating unit having a structure whose acid group is protected by an acid-decomposable group is preferably represented by Formula (1) below.

The “repeating unit represented by Formula (1)”, etc. is also referred to as “repeating unit (1)”, etc., hereinafter.

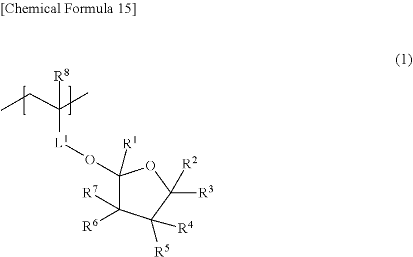

In Formula (1), R⁸ represents a hydrogen atom or an alkyl group (whose number of carbon atoms is preferably 1 to 12, more preferably 1 to 6, and even more preferably 1 to 3), L¹ represents a carbonyl group or a phenylene group, and each of R¹ to R⁷ independently represents a hydrogen atom or an alkyl group.

In Formula (1), R⁸ preferably represents a hydrogen atom or a methyl group, and more preferably represents a methyl group.

In Formula (1), L¹ represents a carbonyl group or a phenylene group, and preferably represents a carbonyl group.

In Formula (1), each of R¹ to R⁷ independently represents a hydrogen atom or an alkyl group. The alkyl group represented by R¹ to R⁷ is synonymous to that represented by R⁸, whose preferred embodiments are also same. In a preferred case, one or more of R¹ to R⁷ represent a hydrogen atom, and in a more preferred case, all of R¹ to R⁷ represent a hydrogen atom.

The repeating unit (1) is preferably represented by Formula (1-A) below, or Formula (1-B) below.

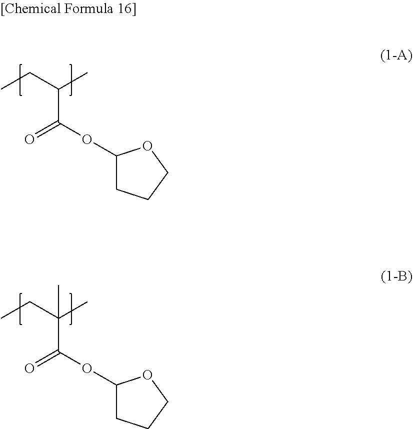

Radical-polymerizable monomer used for forming the repeating unit (1) may be commercially available one, or may be synthesized by any of known methods. For example, it may be synthesized by allowing (meth)acrylic acid to react with a dihydrofuran compound in the presence of an acid catalyst. It may alternatively synthesized by allowing (meth)acrylic acid to polymerize with a precursor monomer, and then allowing the carboxy group or the phenolic hydroxy group to react with a dihydrofuran compound.

The repeating unit having a structure whose acid is protected by an acid-decomposable group is also preferably exemplified by a repeating unit represented by Formula (2) below.

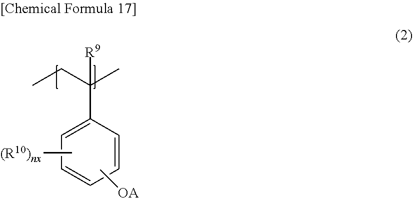

In Formula (2), “A” represents a group that can leave in response to action of a hydrogen atom or an acid. The group that can leave in response to action of an acid is preferably alkyl group (whose number of carbon atoms is preferably 1 to 12, more preferably 1 to 6, and even more preferably 1 to 3), alkoxyalkyl group (whose number of carbon atoms is preferably 2 to 12, more preferably 2 to 6, and even more preferably 2 to 3), aryloxyalkyl group (preferably having a total number of carbon atoms of 7 to 40, more preferably 7 to 30, and even more preferably 7 to 20), alkoxycarbonyl group (whose number of carbon atoms is preferably 2 to 12, more preferably 2 to 6, and even more preferably 2 to 3), and aryloxycarbonyl group (whose number of carbon atoms is preferably 7 to 23, more preferably 7 to 19, and even more preferably 7 to 11). “A” may further have a substituent, wherein the substituent is exemplified by the substituent T.

In Formula (2), R¹⁰ represents a substituent, and is exemplified by the substituent T. R⁹ represents a group synonymous to R⁸ in Formula (1).

In Formula (2), nx represents an integer of 0 to 3.

The group which can leave in response to action of an acid is also preferably a repeating unit having a group that can leave in response to action of an acid, from among the compounds described in paragraphs [0039] to [0049] of JP-2008-197480 A, or preferably any of the compounds described in paragraphs [0052] to [0056] of JP-2012-159830 A (Japanese Patent No. 5191567), the contents of which are incorporated by reference into the present specification.

Specific examples of the repeating unit (2) is listed below, without posing any restriction on understanding of this invention.

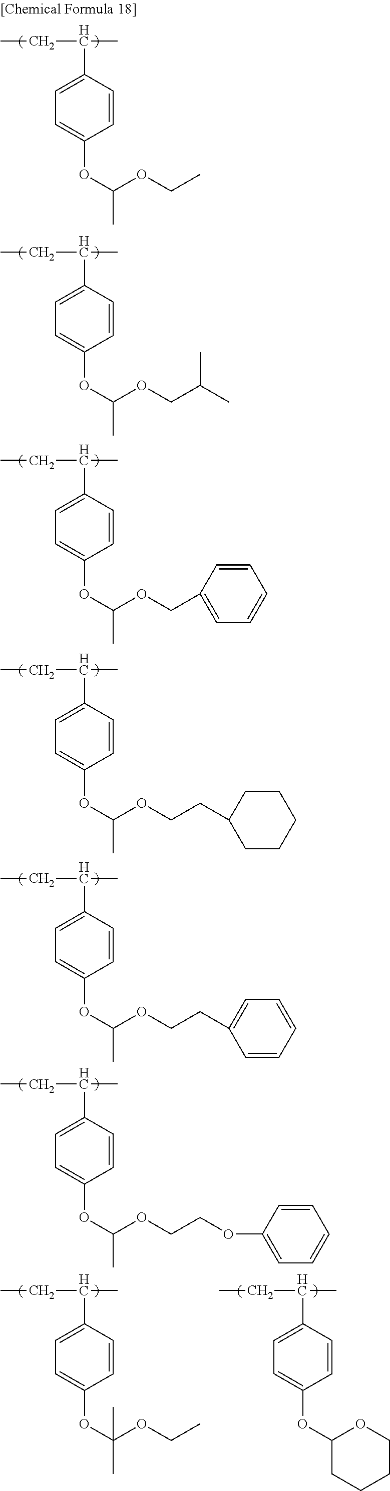

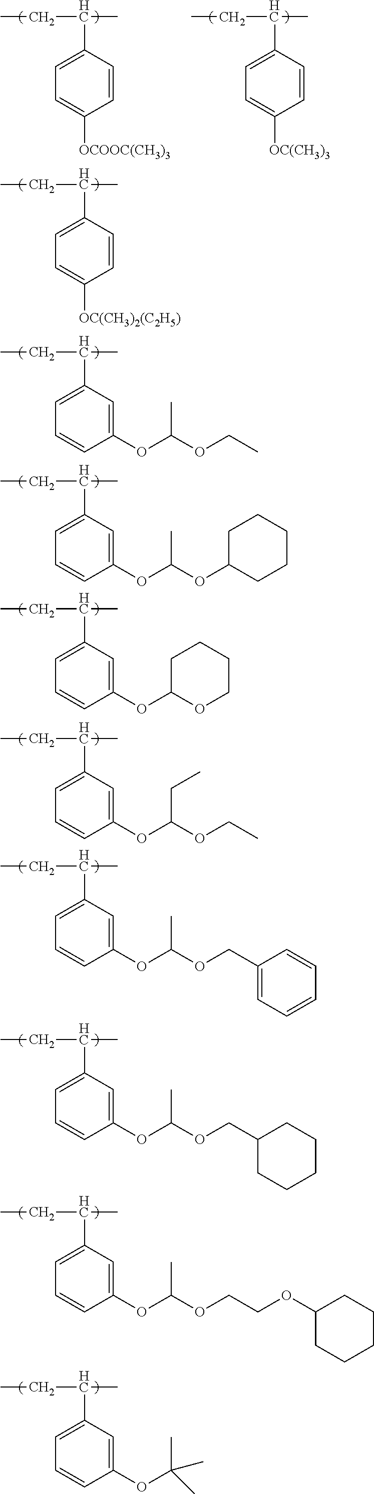

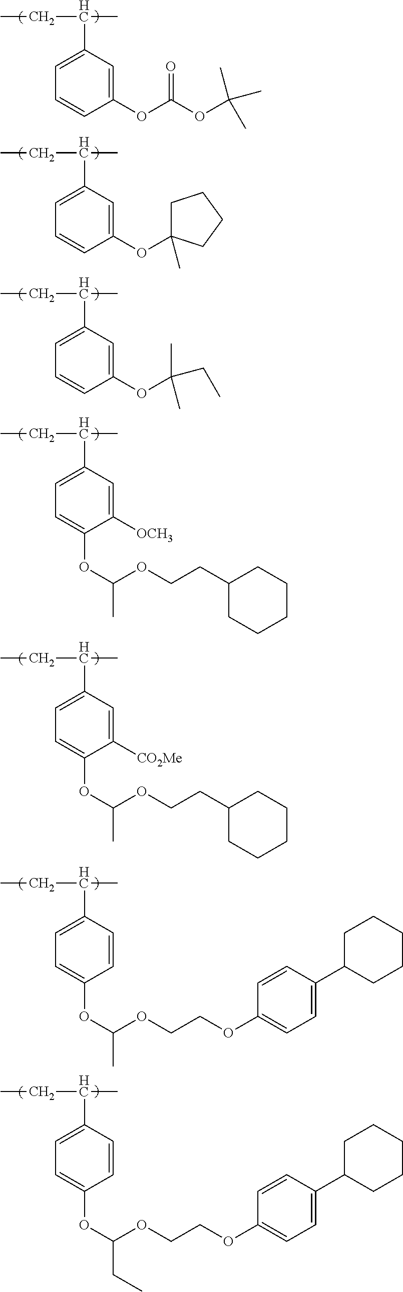

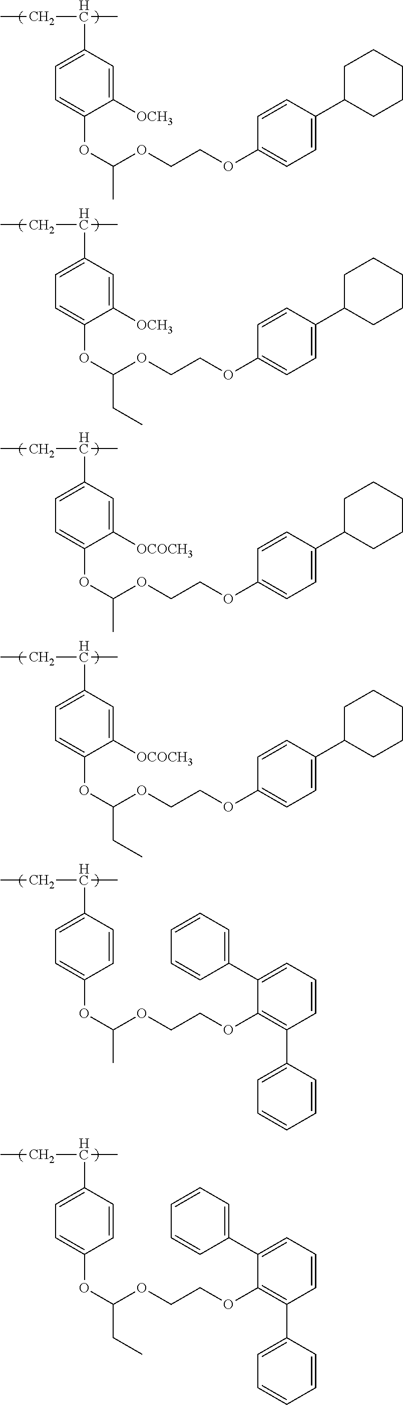

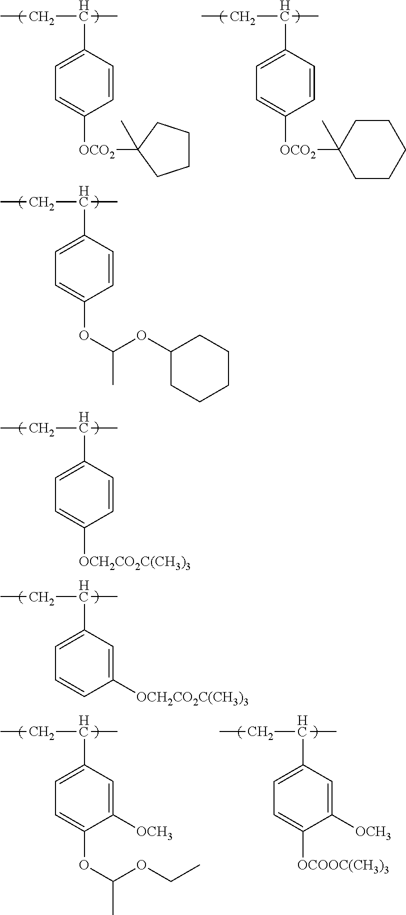

Content of the repeating unit having a structure whose acid group is protected by an acid-decomposable group (preferably, repeating unit (1) or repeating unit (2)), contained in the photo-sensitive layer forming specific resin, is preferably 5 to 80 mol %, more preferably 10 to 70 mol %, and even more preferably 10 to 60 mol %. The acrylic polymer may contain only one kind, or two or more kinds of the repeating unit (1) or the repeating unit (2). When two or more kinds are contained, the total content preferably falls within the aforementioned ranges.

The photo-sensitive layer forming specific resin may also contain a repeating unit that has a crosslinkable group. For details of the crosslinkable group, description in paragraphs [0032] to [0046] of JP-2011-209692 A may be referred to, the contents of which are incorporated by reference into the present specification.

The photo-sensitive layer forming specific resin, although allowed to contain the repeating unit having a crosslinkable group (repeating unit (3)) in one preferred embodiment, is preferably and substantially free of the repeating unit having crosslinkable group. With such design, the photo-sensitive layer after patterned may be removed more effectively. Note that “substantially free of . . . ” means, for example, that the content is 3 mol % or less of the total repeating unit of the photo-sensitive layer forming specific resin, and is preferably 1 mol % or less.

The photo-sensitive layer forming specific resin may also contain other repeating unit (repeating unit (4)). The radical-polymerizable monomer used for forming the repeating unit (4) is typically exemplified by the compounds described in paragraphs [0021] to [0024] of JP-2004-264623 A. Preferred example of the repeating unit (4) is exemplified by a repeating unit derived from at least one selected from the group consisting of hydroxy group-containing unsaturated carboxylic ester, alicyclic structure-containing unsaturated carboxylic ester, styrene, and N-substituted maleimide.

Among them preferred is (meth)acrylic ester that contains alicyclic structure, such as benzyl (meth)acrylate, tricyclo[5.2.1.0^{2,6}]decane-8-yl (meth)acrylate, tricyclo[5.2.1.0^{2,6}]decane-8-yloxyethyl (meth)acrylate, isobornyl (meth)acrylate, cyclohexyl (meth)acrylate, and 2-methylcyclohexyl (meth)acrylate; or, hydrophobic monomer such as styrene.

Only one kind, or two or more kinds of the repeating unit (4) as combined, may be used. Content of the monomer for forming the repeating unit (4), in a case where the repeating unit (4) is contained, is preferably 1 to 60 mol % relative to the total monomers that compose the specific resin, which is more preferably 5 to 50 mol %, and even more preferably 5 to 40 mol %. When two or more kinds are used, the total content preferably falls within the aforementioned ranges.

Various methods for synthesizing the photo-sensitive layer forming specific resin have been known. In one exemplary method, the specific resin may be synthesized with use of a radical-polymerizable monomer mixture that contains at least radical-polymerizable monomers for forming the repeating unit (1), the repeating unit (2) and so forth, and by polymerizing the mixture in an organic solvent in the presence of a radical polymerization initiator.

The photo-sensitive layer forming specific resin is also preferably a copolymer obtainable by adding 2,3-dihydrofuran, to an acid anhydride group in a precursor copolymer copolymerized with an unsaturated multivalent carboxylic anhydride, in the absence of an acid catalyst, in a temperature range from room temperature (25° C.) up to around 100° C.

Also resins below are exemplified as preferred examples.

BzMA/THFMA/t-BuMA [molar ratio=(20 to 60):(35 to 65):(5 to 30)]
BzMA/THFAA/t-BuMA [molar ratio=(20 to 60):(35 to 65):(5 to 30)]
BzMA/THPMA/t-BuMA [molar ratio=(20 to 60):(35 to 65):(5 to 30)]
BzMA/PEES/t-BuMA [molar ratio=(20 to 60):(35 to 65):(5 to 30)]

BzMA represents benzyl methacrylate, THFMA represents tetrahydrofuran-2-yl methacrylate, t-BuMA represents t-butyl methacrylate, THFAA represents tetrahydrofuran-2-yl acrylate, THPMA represents tetrahydro-2H-pyrane-2-yl methacrylate, and PEES represents p-ethoxyethoxystyrene.

Regarding the photo-sensitive layer forming specific resin used for positive development, those described in JP-2013-011678 A may be referred to, the contents of which are incorporated by reference into this specification.

From the viewpoint of improving the patternability during development, content of the photo-sensitive layer forming specific resin is preferably 20 to 99% by mass, relative to the total mass of the photo-sensitive layer, which is more preferably 40 to 99% by mass, and even more preferably 70 to 99% by mass. The photo-sensitive layer may contain only one kind, or two or more kinds of the photo-sensitive layer forming specific resin. When two or more kinds are used, the total content preferably falls within the aforementioned ranges.

Content of the photo-sensitive layer forming specific resin is also preferably 10% by mass or more, relative to the total mass of the resin components contained in the photo-sensitive layer, which is more preferably 50% by mass or more, and even more preferably 90% by mass or more.

The photo-sensitive layer forming specific resin preferably has a weight-average molecular weight of 10,000 or larger, which is more preferably 20,000 or larger, and even more preferably 35,000 or larger. The upper limit value, although not specifically limited, is preferably 100,000 or below, which may be 70,000 or below, and even may be 50,000 or below.

In the photo-sensitive layer forming specific resin, content of a component having a weight-average molecular weight of 1,000 or smaller is preferably 10% by mass or less relative to the total mass of the photo-sensitive layer forming specific resin, which is more preferably 5% by mass or less.

The specific resin preferably has a polydispersity (weight-average molecular weight/number-average molecular weight) of 1.0 to 4.0, which is more preferably 1.1 to 2.5.

### [Photo-Acid Generator]

The photo-sensitive layer preferably contains an additional photo-acid generator.

The photo-acid generator preferably decomposes to an extent of 80%, when the photo-sensitive layer is irradiated at 365 nm under an irradiation dose of 100 mJ/cm².

Decomposability of the photo-acid generator may be determined by the method below. The photo-sensitive layer forming composition will be detailed later.

A film of the photo-sensitive layer forming composition is formed on a silicon wafer substrate, heated at 100° C. for one minutes, and after the heating, the photo-sensitive layer is exposed with light of 365 nm under an irradiation dose of 100 mJ/cm². The heated photo-sensitive layer is specified to be 700 nm thick. The silicon wafer substrate having the photo-sensitive layer formed thereon is then immersed in a 50:50 (mass ratio) mixed solution of methanol and tetrahydrofuran (THF) for 10 minutes under sonication. After the immersion, an extract extracted into the solution is analyzed by HPLC (high performance liquid chromatography), and decomposition ratio of the photo-acid generator is calculated by using the equation below:

Decomposition ratio (%)={Amount of decomposition product (mol)/Amount of photo-acid generator contained in photo-sensitive layer before exposure (mol)}×100

The photo-acid generator preferably decomposes to an extent of 85 mol % or more when the photo-sensitive layer is irradiated at 365 nm under an irradiation dose of 100 mJ/cm².

### —Oxime Sulfonate Compound—

The photo-acid generator is preferably a compound that contains an oxime sulfonate group (also simply referred to as “oxime sulfonate compound”, hereinafter).

The oxime sulfonate compound, although not specifically limited so far as it has an oxime sulfonate group, is preferably those represented by Formula (OS-1) below, as well as Formula (OS-103), Formula (OS-104), or Formula (OS-105) described later.

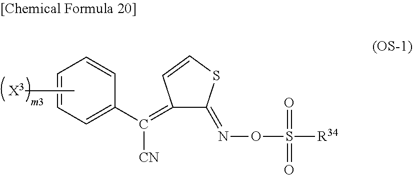

In Formula (OS-1), X³ represents an alkyl group, alkoxy group, or halogen atom. If there are a plurality of (X³)s, they may be same or different. The alkyl group and alkoxy group represented by X³ may have a substituent. The alkyl group represented by X³ is preferably straight-chain or branched alkyl group having 1 to 4 carbon atoms. The alkoxy group represented by X³ is preferably straight-chain or branched alkoxy group having 1 to 4 carbon atoms. The halogen atom represented by X³ is preferably chlorine atom or fluorine atom.

In Formula (OS-1), m3 represents an integer of 0 to 3, and is preferably 0 or 1. If m3 is 2 or 3, a plurality of (X³)s may be same or different.

In Formula (OS-1), R³⁴ represents an alkyl group or an aryl group, and preferably represents an alkyl group having 1 to 10 carbon atoms, alkoxy group having 1 to 10 carbon atoms, halogenated alkyl group having 1 to 5 carbon atoms, halogenated alkoxy group having 1 to 5 carbon atoms, phenyl group optionally substituted by W, naphthyl group optionally substituted by W, or anthranyl group optionally substituted by W. W represents a halogen atom, cyano group, nitro group, alkyl group having 1 to 10 carbon atoms, alkoxy group having 1 to 10 carbon atoms, halogenated alkyl group having 1 to 5 carbon atoms or halogenated alkoxy group having 1 to 5 carbon atoms, aryl group having 6 to 20 carbon atoms, and halogenated aryl group having 6 to 20 carbon atoms.

A particularly preferred compound is represented by Formula (OS-1), in which m3 is 3, X³ represents a methyl group, X³ is bound at the ortho position, and R³⁴ represents a straight-chain alkyl group having 1 to 10 carbon atoms, 7,7-dimethyl-2-oxonorbonylmethyl group, or, p-tolyl group.

Specific examples of the oxime sulfonate compound represented by Formula (OS-1) are exemplified by the compounds below, having been described in paragraphs [0064] to [0068] of JP-2011-209692 A, and paragraphs [0158] to [0167] of JP-2015-194674 A, the contents of which are incorporated by reference into the present patent specification.

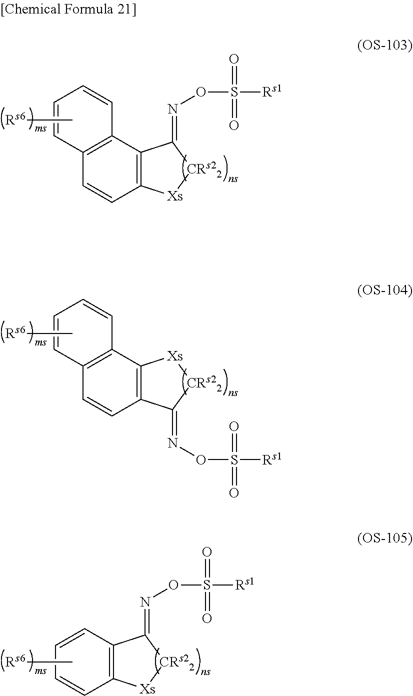

In Formula (OS-103) to Formula (OS-105), R^{s1} represents an alkyl group, aryl group or heteroaryl group, R^{s2} occasionally in the plural independently represents a hydrogen atom, alkyl group, aryl group or halogen atom, R^{s6} occasionally in the plural independently represents a halogen atom, alkyl group, alkyloxy group, sulfonic acid group, amino sulfonyl group or alkoxysulfonyl group, Xs represents O or S, ns represents 1 or 2, and ms represents an integer of 0 to 6.

In Formula (OS-103) to Formula (OS-105), the alkyl group (whose number of carbon atoms is preferably 1 to 30), aryl group (whose number of carbon atoms is preferably 6 to 30) or heteroaryl group (whose number of carbon atoms is preferably 4 to 30), all represented by R^{s1}, may have the substituent T.

In Formula (OS-103) to Formula (OS-105), R^{s2} preferably represents a hydrogen atom, alkyl group (whose number of carbon atoms is preferably 1 to 12) or aryl group (whose number of carbon atoms is preferably 6 to 30), and more preferably represents a hydrogen atom or alkyl group. A preferred case is that one or two of (R^{s2})s, occasionally in the plural in the compound, represent an alkyl group, aryl group or halogen atom; a more preferred case is that one R^{s2} represents an alkyl group, aryl group or halogen atom; and a particularly preferred case is that one R^{s2} represents an alkyl group, and each of the residual (R^{s2})s represents a hydrogen atom. The alkyl group or aryl group represented by R^{s2} may have the substituent T.

In Formula (OS-103), Formula (OS-104) or Formula (OS-105), Xs represents O or S, where O is preferred. In Formulae (OS-103) to (OS-105), a ring that contains Xs as the ring member is a five-membered ring or six-membered ring.

In Formula (OS-103) to Formula (OS-105), if ns represents 1 or 2 and Xs represents 0, then ns is preferably 1. Moreover, if Xs represents S, then ns is preferably 2.

In Formula (OS-103) to Formula (OS-105), the alkyl group (whose number of carbon atoms is preferably 1 to 30) and the alkyloxy group (whose number of carbon atoms is preferably 1 to 30), both represented by R^{s6}, may have a substituent.

In Formula (OS-103) to Formula (OS-105), ms represents an integer of 0 to 6, which is more preferably 0 to 2, even more preferably 0 or 1, and particularly preferably 0.

The compound represented by Formula (OS-103) is particularly preferably a compound represented by Formula (OS-106), Formula (OS-110) or Formula (OS-111) below, the compound represented by Formula (OS-104) is particularly preferably a compound represented by Formula (OS-107), and the compound represented by Formula (OS-105) is particularly preferably a compound represented by Formula (OS-108) or Formula (OS-109) below.

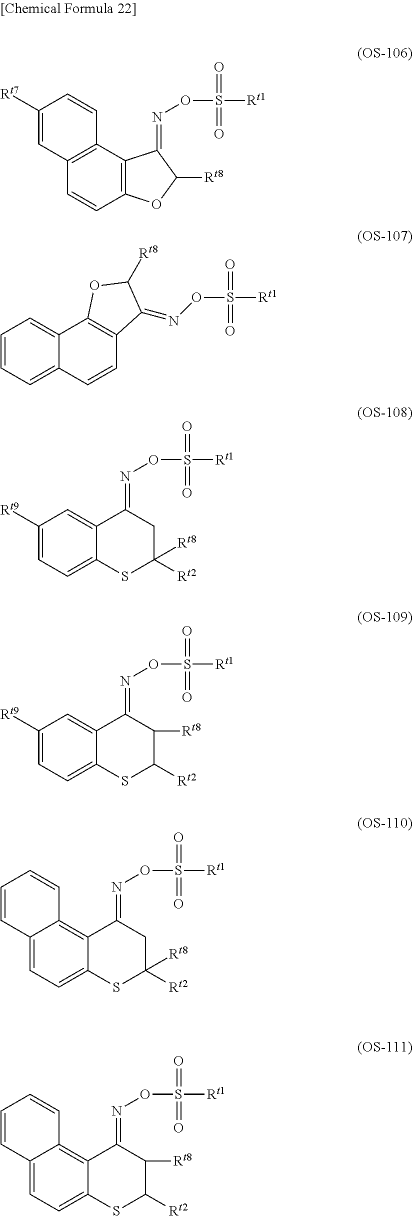

In Formula (OS-106) to Formula (OS-111), R^{t1} represents an alkyl group, aryl group or heteroaryl group, R^{t7} represents a hydrogen atom or bromine atom, R^{t8} represents a hydrogen atom, alkyl group having 1 to 8 carbon atoms, halogen atom, chloromethyl group, bromomethyl group, bromoethyl group, methoxymethyl group, phenyl group or chlorophenyl group, R^{t9} represents a hydrogen atom, halogen atom, methyl group or methoxy group, and R^{t2} represents a hydrogen atom or methyl group.

In Formula (OS-106) to Formula (OS-111), R^{t7} represents a hydrogen atom or bromine atom, wherein hydrogen atom is preferred.

In Formula (OS-106) to Formula (OS-111), R^{t8} represents a hydrogen atom, alkyl group having 1 to 8 carbon atoms, halogen atom, chloromethyl group, bromomethyl group, bromoethyl group, methoxymethyl group, phenyl group or chlorophenyl group, among which preferred is alkyl group having 1 to 8 carbon atoms, halogen atom or phenyl group, more preferred is alkyl group having 1 to 8 carbon atoms, even more preferred is alkyl group having 1 to 6 carbon atoms, and yet more preferred is methyl group.

In Formula (OS-106) to Formula (OS-111), R^{t9} represents a hydrogen atom, halogen atom, methyl group or methoxy group, among which hydrogen atom is preferred.

R^{t2} represents a hydrogen atom or methyl group, and preferably represents a hydrogen atom.

In the oxime sulfonate compound, oxime may have either stereochemistry (E or Z, etc.), or may have both structures mixed therein.

Regarding specific examples of the oxime sulfonate compounds represented by Formula (OS-103) to Formula (OS-105), the compounds described in paragraphs [0088] to [0095] of JP-2011-209692 A, and paragraphs [0168] to [0194] of JP-2015-194674 A may be referred to, the contents of which are incorporated by reference into this specification.

Other preferred embodiments of the oxime sulfonate compound that contains at least one oxime sulfonate group are exemplified by compounds represented by Formula (OS-101) and Formula (OS-102) below.

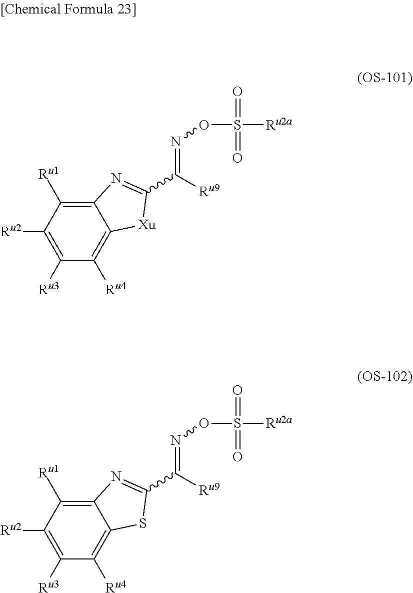

In Formula (OS-101) or Formula (OS-102), R^{u9} represents a hydrogen atom, alkyl group, alkenyl group, alkoxy group, alkoxycarbonyl group, acyl group, carbamoyl group, sulfamoyl group, sulfo group, cyano group, aryl group or heteroaryl group. An embodiment with R^{u9} representing a cyano group or aryl group is more preferred, and an embodiment with R^{u9} representing a cyano group, phenyl group or naphthyl group is even more preferred.

In Formula (OS-101) or Formula (OS-102), R^{u2a} represents an alkyl group or aryl group.

In Formula (OS-101) or Formula (OS-102), Xu represents —O—, —S—, —NH—, —NR^{u5}—, —CH₂—, —CR^{u6}H—or CR^{u6}R^{u7}—, and each of R^{u5} to R^{u7} independently represents an alkyl group or aryl group.

In Formula (OS-101) or Formula (OS-102), each of R^{u1} to R^{u4} independently represents a hydrogen atom, halogen atom, alkyl group, alkenyl group, alkoxy group, amino group, alkoxycarbonyl group, alkylcarbonyl group, arylcarbonyl group, amido group, sulfo group, cyano group or aryl group. Two of R^{u1} to R^{u4} may bond to each other to form a ring. In this case, the rings may be condensed to form a condensed ring together with a benzene ring. Each of R^{u1} to R^{u4} preferably represents a hydrogen atom, halogen atom or alkyl group, and also at least two of R^{u1} to R^{u4} preferably bond to each other to form an aryl group. A particularly preferred embodiment relates to that all of R^{u1} to R^{u4} individually represent a hydrogen atom. Each of these substituents may further have a substituent.

The compound represented by Formula (OS-101) is more preferably a compound represented by Formula (OS-102).

In the oxime sulfonate compound, each of oxime and benzothiazole ring may have either stereochemistry (E or Z, etc.), or may have both structures mixed therein.

Regarding specific examples of the compound represented by Formula (OS-101), descriptions in paragraphs [0102] to [0106] of JP-2011-209692 A, and paragraphs [0195] to [0207] of JP-2015-194674 A may be referred to, the contents of which are incorporated by reference into this specification.

Among these compounds, preferred are b-9, b-16, b-31 and b-33.

Commercially available products are exemplified by WPAG-336 (from FUJIFILM Wako Pure Chemical Corporation), WPAG-443 (from FUJIFILM Wako Pure Chemical Corporation), and MBZ-101 (from Midori Kagaku Co., Ltd.).

Such other photo-acid generator sensitive to active ray is preferably free of 1,2-quinone diazide compound. This is because 1,2-quinone diazide compound, although capable of producing a carboxy group as a result of a sequential photochemical reaction, can only demonstrate a quantum yield as small as 1 or below, proving a low sensitivity as compared with the oxime sulfonate compound.

In contrast, the oxime sulfonate compound can produce an acid in response to active ray, and the acid can catalyze deprotection of the protected acid group, so that an acid produced by the action of a single photon can contribute to a large number of runs of deprotection reaction, possibly demonstrating a quantum yield exceeding 1, up to a large value such as several powers of 10, thereby resulting in high sensitivity as a result of chemical amplification.

Also since the oxime sulfonate compound has a broad r conjugation system, and therefore shows absorption up to longer wavelength regions, so that it can demonstrate very high sensitivity not only to deep ultraviolet (DUV), ArF laser, KrF laser and i-line, but also to g-line.

Use of tetrahydrofuranyl group as an acid-decomposable group in the photo-sensitive layer will be successful in achieving acid-decomposability equivalent to or larger than that of acetal or ketal. This enables thorough consumption of the acid-decomposable group by post-baking within a shorter time. Moreover, combined use with the oxime sulfonate compound, as the other photo-acid generator, can accelerate production of sulfonic acid and can therefore promote acid production, thus promoting decomposition of the acid-decomposable group or the resin. The acid obtainable as a result of decomposition of the oxime sulfonate compound is a sulfonic acid whose molecular size is small, and can therefore rapidly diffuse in the cured film, making the photo-sensitive layer more sensitive.

Amount of use of the photo-acid generator is preferably 0.1 to 20% by mass, relative to the total mass of the photo-sensitive layer, which is more preferably 0.5 to 18% by mass, even more preferably 0.5 to 10% by mass, yet more preferably 0.5 to 3% by mass, and furthermore preferably 0.5 to 1.2% by mass.

One kind of the photo-acid generator may be used alone, or two or more kinds may be used in a combined manner. When two or more kinds are used, the total content preferably falls within the aforementioned ranges.

### [Basic Compound]

The photo-sensitive layer preferably contains a basic compound, from the viewpoint of shelf stability of a solution of the photo-sensitive layer forming composition described later.

The basic compound used herein is freely selectable from those known for use in chemical amplification resist, and is exemplified by aliphatic amine, aromatic amine, heterocyclic amine, quaternary ammonium hydroxide, and quaternary ammonium salt of carboxylic acid.

The aliphatic amine is exemplified by trimethylamine, diethylamine, triethylamine, di-n-propylamine, tri-n-propylamine, di-n-pentylamine, tri-n-pentylamine, diethanolamine, triethanolamine, dicyclohexylamine, and dicyclohexylmethylamine.

The aromatic amine is exemplified by aniline, benzylamine, N,N-dimethylaniline, and diphenylamine.

The heterocyclic amine is exemplified by pyridine, 2-methylpyridine, 4-methylpyridine, 2-ethylpyridine, 4-ethylpyridine, 2-phenylpyridine, 4-phenylpyridine, N-methyl-4-phenylpyridine, 4-dimethylaminopyridine, imidazol, benzimidazol, 4-methylimidazol, 2-phenylbenzimidazol, 2,4,5-triphenylimidazol, nicotine, nicotinic acid, nicotinamide, quinoline, 8-oxyquinoline, pyrazine, pyrazole, pyridazine, purine, pyrrolidine, piperidine, cyclohexylmorpholinoethyl thiourea, piperazine, morpholine, 4-methylmorpholine, 1,5-diazabicyclo[4.3.0]-5-nonene, and 1,8-diazabicyclo[5.3.0]-7-undecene.

The quaternary ammonium hydroxide is exemplified by tetramethylammonium hydroxide, tetraethylammonium hydroxide, tetra-n-butylammonium hydroxide, and tetra-n-hexylammonium hydroxide.

The quaternary ammonium salt of carboxylic acid is exemplified by tetramethylammonium acetate, tetramethylammonium benzoate, tetra-n-butylammonium acetate, and tetra-n-butylammonium benzoate.

Content of the basic compound, when contained in the photo-sensitive layer, is preferably 0.001 to 1 part by mass per 100 parts by mass of the photo-sensitive layer forming specific resin, and more preferably 0.002 to 0.5 parts by mass.

One kind of the basic compound may be used alone, or two or more kinds may be used in a combined manner, wherein combined use of two or more kinds is preferred, combined use of two kinds is more preferred, and combined use of two kinds of heterocyclic amine is even more preferred. When two or more kinds are used, the total content preferably falls within the aforementioned ranges.

### [Surfactant]

The photo-sensitive layer preferably contains a surfactant, from the viewpoint of improving coatability of the photo-sensitive layer forming composition described later.

Any of anionic, cationic, nonionic, or amphoteric surfactant is usable, wherein nonionic surfactant is preferred.

The nonionic surfactant is exemplified by higher alkyl ethers of polyoxyethylene, higher alkylphenyl ethers of polyoxyethylene, higher fatty acid diesters of polyoxyethylene glycol, fluorine-containing surfactants, and silicone-based surfactants.

The fluorine-containing surfactant, or silicone-based surfactant is more preferably contained as the surfactant.

These fluorine-containing surfactants, or, the silicone-based surfactants are exemplified by those described for example in JP-S62-036663 A, JP-S61-226746 A, JP-S61-226745 A, JP-S62-170950 A, JP-S63-034540 A, JP-H07-230165 A, JP-H08-062834 A, JP-H09-054432 A, JP-H09-005988 A, and JP-2001-330953 A. Also commercially available surfactants may be used.

The commercially available surfactant usable here is exemplified by fluorine-containing surfactants or silicone-based surfactant, including Eftop EF301, EF303 (both from Shin Akita Kasei K.K.), Fluorad FC430, 431 (both from Sumitomo 3M Ltd.), Megaface F171, F173, F176, F189, R08 (all from DIC Corporation), Surflon S-382, SC101, 102, 103, 104, 105, 106 (all from AGC Seimi Chemical Co., Ltd.), and PolyFox Series such as PF-6320 (from OMNOVA Solutions Inc.). Also polysiloxane polymer KP-341 (from Shin-Etsu Chemical Co., Ltd.) is usable as the silicone-based surfactant.

As a preferred example of the surfactant, also exemplified is a copolymer that contains repeating unit A and repeating unit B represented by Formula (41) below, having a weight-average molecular weight (Mw), when measured by gel permeation chromatography while using tetrahydrofuran (THF) as a solvent, of 1,000 or larger and 10,000 or smaller in polystyrene equivalent.

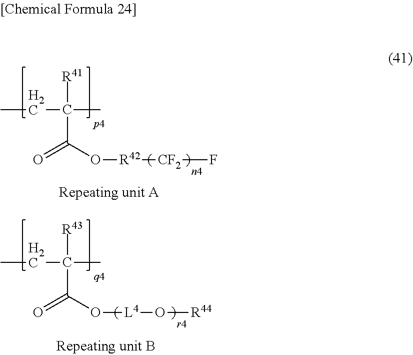

In Formula (41), each of R⁴¹ and R⁴³ independently represents a hydrogen atom or a methyl group, R⁴² represents a straight chain alkylene group having 1 or more and 4 or less carbon atoms, R⁴⁴ represents a hydrogen atom or an alkyl group having 1 or more and 4 or less carbon atoms, L⁴ represents an alkylene group having 3 or more and 6 or less carbon atoms, each of p4 and q4 represents mass percentage that represents polymerization ratio, p4 represents a value of 10% by mass or larger and 80% by mass or smaller, q4 represents a value of 20% by mass or larger and 90% by mass or smaller, r4 represents an integer of 1 or larger and 18 or smaller, and n4 represents an integer of 1 or larger and 10 or smaller.

In Formula (41), L⁴ preferably represents a branched alkylene group represented by Formula (42) below. In Formula (42), R⁴⁵ represents an alkyl group having 1 or more and 4 or less carbon atoms. From the viewpoint of wetting over the surface to be coated, the alkyl group more preferably has 1 or more and 3 or less carbon atoms, and more preferably has 2 or 3 carbon atoms.

—CH₂—CH(R⁴⁵)— (42)

The copolymer preferably has a weight-average molecular weight of 1,500 or larger and 5,000 or smaller.

Amount of addition of the surfactant, when contained in the photo-sensitive layer, is preferably 10 parts by mass or less, per 100 parts by mass of the specific resin, more preferably 0.01 to 10 parts by mass, and even more preferably 0.01 to 1 parts by mass.

Only one kind of, or two or more kinds of the surfactant as mixed may be used. When two or more kinds are used, the total content preferably falls within the aforementioned ranges.

### [Other Components]

The photo-sensitive layer may have further added thereto as necessary, any of known additives such as antioxidant, plasticizer, thermal radical generator, thermal acid generator, acid proliferator, UV absorber, thickener, and organic or inorganic anti-settling agent, allowing use of one kind, or two or more kind of each additive. Regarding details of these additives, description in paragraphs [0143] to [0148] of JP-2011-209692 A may be referred to, the contents of which are incorporated by reference into the present specification.

### [Thickness]

The photo-sensitive layer in this invention preferably has a thickness (film thickness) of 0.1 μm or larger, from the viewpoint of improving resolving power, which is more preferably 0.5 μm or larger, even more preferably 0.75 μm or larger, and particularly preferably 0.8 μm or larger. The upper limit value of the thickness of the photo-sensitive layer is preferably 10 μm or below, more preferably 5.0 μm or below, and even more preferably 2.0 μm or below.

The total thickness of the photo-sensitive layer and the protective layer is preferably 0.2 μm or larger, more preferably 1.0 μm or larger, and even more preferably 2.0 μm or larger. The upper limit value is preferably 20.0 μm or below, more preferably 10.0 μm or below, and even more preferably 5.0 μm or below.

### [Developing Solution]

The photo-sensitive layer in this invention is intended for development with use of a developing solution.

The developing solution preferably contains an organic solvent.

Content of the organic solvent relative to the total mass of the developing solution is preferably 90 to 100% by mass, and more preferably 95 to 100% by mass. The developing solution may be solely composed of an organic solvent.

Method for developing the photo-sensitive layer with use of the developing solution will be described later.

### —Organic Solvent—

The organic solvent contained in the developing solution preferably has an sp value of smaller than 19 MPa^{1/2}, and more preferably 18 MPa^{1/2} or smaller.

The organic solvent contained in the developing solution is exemplified by polar solvents such as ketone solvents, ester solvents and amide solvent; and hydrocarbon solvents.

The ketone solvents are exemplified by 1-octanone, 2-octanone, 1-nonanone, 2-nonanone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetone alcohol, acetyl carbinol, acetophenone, methyl naphthyl ketone, isophorone, and propylene carbonate.

The ester solvents are exemplified by methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, and propyl lactate.

The amide solvents usable here are exemplified by N-methyl-2-pyrrolidone, N,N-dimethylacetamide, N,N-dimethylformamide, hexamethylphosphoric triamide, and 1,3-dimethyl-2-imidazolidinone.

The hydrocarbon solvents are exemplified by aromatic hydrocarbon solvents such as toluene and xylene; and aliphatic hydrocarbon solvents such as pentane, hexane, octane, and decane.

Only one kind, or two or more kinds of organic solvent may be used. Any solvent other than the aforementioned organic solvents may be used in a mixed manner. It is, however, preferred that content of water, relative to the total mass of the developing solution, is less than 10% by mass, and more preferably substantially free of water. Now, “substantially free of water” means, for example, that the water content, relative to the total mass of the developing solution, is 3% by mass or less, and is more preferably below the measurement limit.

That is, the amount of use of the organic solvent in the organic developing solution is preferably 90% by mass or more and 100% by mass or less, relative to the total amount of the developing solution, and is more preferably 95% by mass or more and 100% by mass or less.

In particular, the organic developing solution preferably contains at least one kind of organic solvent selected from the group consisting of the ketone solvents, ester solvents and amide solvents.

The organic developing solution may also contain an appropriate amount of an optional basic compound. Examples of the basic compound may be exemplified by those having been described previously regarding the basic compound.

The organic developing solution preferably has a vapor pressure at 23° C. of 5 kPa or lower, more preferably 3 kPa or lower, and even more preferably 2 kPa or lower. By limiting the vapor pressure of the organic developing solution to 5 kPa or lower, the developing solution will be suppressed from vaporizing on the photo-sensitive layer, or within a development cup, thereby improving temperature uniformity over the surface of the photo-sensitive layer, and improving dimensional stability of the developed photo-sensitive layer as a consequence.

The solvent having a vapor pressure of 5 kPa or lower is specifically exemplified by ketone solvents such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone, and methyl isobutyl ketone; ester solvents such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, butyl formate, propyl formate, ethyl lactate, butyl lactate, and propyl lactate; amide solvents such as N-methyl-2-pyrrolidone, N,N-dimethylacetamide, and N,N-dimethylformamide; hydrocarbon solvents such as toluene and xylene; and aliphatic hydrocarbon solvents such as octane and decane.

The solvent having a vapor pressure of 2 kPa or lower, which is a particularly preferred range, is specifically exemplified by ketone solvents such as 1-octanone, 2-octanone, 1-nonanone, 2-nonanone, 4-heptanone, 2-hexanone, diisobutyl ketone, cyclohexanone, methylcyclohexanone, and phenylacetone; ester solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, ethyl lactate, butyl lactate, and propyl lactate; amide solvents such as N-methyl-2-pyrrolidone, N,N-dimethylacetamide, and N,N-dimethylformamide; aromatic hydrocarbon solvents such as xylene; and aliphatic hydrocarbon solvents such as octane and decane.

### —Surfactant—

The developing solution may contain a surfactant.

The surfactant is not specifically limited, and for which those having been described previously in the section titled Protective Layer are applicable.

The amount of addition of the surfactant, when added to the developing solution, is usually 0.001 to 5% by mass relative to the total mass of the developing solution, preferably 0.005 to 2% by mass, and even more preferably 0.01 to 0.5% by mass.

### [Photo-Sensitive Layer Forming Composition]

The photo-sensitive layer forming composition of this invention is a compound used for forming the photo-sensitive layer contained in the laminate of this invention.

In the laminate of this invention, the photo-sensitive layer may be formed, for example, by applying the photo-sensitive layer forming composition over the protective layer, followed by drying. Regarding method of application, a description later on the method for applying the protective layer forming composition for the protective layer may be referred to.

The photo-sensitive layer forming composition preferably contains the aforementioned components contained in the photo-sensitive layer (for example, photo-sensitive layer forming specific resin, photo-acid generator, basic compound, surfactant, and, other components, etc.), and the solvent. These components contained in the photo-sensitive layer are more preferably dissolved or dispersed in the solvent, and more preferably dissolved in the solvent.

Regarding the content of the components contained in the photo-sensitive layer forming composition, the contents of the aforementioned individual components relative to the total mass of the photo-sensitive layer are preferably deemed to be the contents relative to the total solid content of the photo-sensitive layer forming composition.

### —Organic Solvent—

The organic solvent used for the photo-sensitive layer forming composition may be any of known organic solvents, and is exemplified by ethylene glycol monoalkyl ethers, ethylene glycol dialkyl ethers, ethylene glycol monoalkyl ether acetates, propylene glycol monoalkyl ethers, propylene glycol dialkyl ethers, propylene glycol monoalkyl ether acetates, diethylene glycol dialkyl ethers, diethylene glycol monoalkyl ether acetates, dipropylene glycol monoalkyl ethers, dipropylene glycol dialkyl ethers, dipropylene glycol monoalkyl ether acetates, esters, ketones, amides, and lactones.

The organic solvent is exemplified by:

(1) ethylene glycol monoalkyl ethers such as ethylene glycol monomethyl ether, ethylene glycol monoethyl ether, ethylene glycol monopropyl ether, and ethylene glycol monobutyl ether;

(2) ethylene glycol dialkyl ethers such as ethylene glycol dimethyl ether, ethylene glycol diethyl ether, and ethylene glycol dipropyl ether;

(3) ethylene glycol monoalkyl ether acetates such as ethylene glycol monomethyl ether acetate, ethylene glycol monoethyl ether acetate, ethylene glycol monopropyl ether acetate, and ethylene glycol monobutyl ether acetate;

(4) propylene glycol monoalkyl ethers such as propylene glycol monomethyl ether, propylene glycol monoethyl ether, propylene glycol monopropyl ether, and propylene glycol monobutyl ether;

(5) propylene glycol dialkyl ethers such as propylene glycol dimethyl ether, and propylene glycol diethyl ether;

(6) propylene glycol monoalkyl ether acetates such as propylene glycol monomethyl ether acetate, propylene glycol monoethyl ether acetate, propylene glycol monopropyl ether acetate, and propylene glycol monobutyl ether acetate;

(7) diethylene glycol dialkyl ethers such as diethylene glycol dimethyl ether, diethylene glycol diethyl ether, and diethylene glycol ethyl methyl ether;

(8) diethylene glycol monoalkyl ether acetates such as diethylene glycol monomethyl ether acetate, diethylene glycol monoethyl ether acetate, diethylene glycol monopropyl ether acetate, and diethylene glycol monobutyl ether acetate;

(9) dipropylene glycol monoalkyl ethers such as dipropylene glycol monomethyl ether, dipropylene glycol monoethyl ether, dipropylene glycol monopropyl ether, and dipropylene glycol monobutyl ether;

(10) dipropylene glycol dialkyl ethers such as dipropylene glycol dimethyl ether, dipropylene glycol diethyl ether, and dipropylene glycol ethyl methyl ether;

(11) dipropylene glycol monoalkyl ether acetates such as dipropylene glycol monomethyl ether acetate, dipropylene glycol monoethyl ether acetate, dipropylene glycol monopropyl ether acetate, and dipropylene glycol monobutyl ether acetate;

(12) lactate esters such as methyl lactate, ethyl lactate, n-propyl lactate, isopropyl lactate, n-butyl lactate, isobutyl lactate, n-amyl lactate, and isoamyl lactate;

(13) aliphatic carboxylic esters such as n-butyl acetate, isobutyl acetate, n-amyl acetate, isoamyl acetate, n-hexyl acetate, 2-ethylhexyl acetate, ethyl propionate, n-propyl propionate, isopropyl propionate, n-butyl propionate, isobutyl propionate, methyl butyrate, ethyl butyrate, n-propyl butyrate, isopropyl butyrate, n-butyl butyrate, and isobutyl butyrate;

(14) other esters including hydroxyethyl acetate, ethyl 2-hydroxy-2-methylpropionate, ethyl 2-hydroxy-3-methylbutyrate, methoxyethyl acetate, ethoxyethyl acetate, methyl 3-methoxypropionate, ethyl 3-methoxypropionate, methyl 3-ethoxypropionate, ethyl 3-ethoxypropionate, 3-methoxybutyl acetate, 3-methyl-3-methoxybutyl acetate, 3-methyl-3-methoxybutyl propionate, 3-methyl-3-methoxybutyl butyrate, methyl acetoacetate, ethyl acetoacetate, methyl pyruvate, and ethyl pyruvate;

(15) ketones such as methyl ethyl ketone, methyl propyl ketone, methyl n-butyl ketone, methyl isobutyl ketone, 2-heptanone, 3-heptanone, 4-heptanone, and cyclohexanone;

(16) amides such as N-methylformamide, N,N-dimethylformamide, N-methylacetamide, N,N-dimethylacetamide, and N-methylpyrrolidone; and

(17) lactones such as γ-butyrolactone.

These organic solvents allow further addition of any optional organic solvent such as benzyl ethyl ether, dihexyl ether, ethylene glycol monophenyl ether acetate, diethylene glycol monomethyl ether, diethylene glycol monoethyl ether, isophorone, caproic acid, caprylic acid, 1-octanol, 1-nonanol, benzyl alcohol, anisole, benzyl acetate, ethyl benzoate, diethyl oxalate, diethyl maleate, ethylene carbonate, and propylene carbonate.

From among these organic solvents, propylene glycol monoalkyl ether acetates, or, diethylene glycol dialkyl ethers are preferred. Diethylene glycol ethyl methyl ether, or, propylene glycol monomethyl ether acetate is particularly preferred.

Content of the organic solvent, when contained in the photo-sensitive layer forming composition, is preferably 1 to 3,000 parts by mass per 100 parts by mass of the photo-sensitive layer forming specific resin, more preferably 5 to 2,000 parts by mass, and even more preferably 10 to 1,500 parts by mass.

One kind of the organic solvent may be used alone, or two or more kinds may be used in a combined manner.

When two or more kinds are used, the total content preferably falls within the aforementioned ranges.

### (Laminate Forming Kit)

A laminate forming kit of this invention contains A and B below:

A: a composition that contains the specific resin, and is used for forming the protective layer contained in the laminate of this invention; and

B: a composition used for forming the photo-sensitive layer contained in the laminate of this invention.

The laminate forming kit of this invention may further contain the aforementioned organic semiconductor layer forming composition or the resin layer forming composition.

### (Method for Patterning Organic Layer)

A preferred embodiment of the patterning method suitably applicable to this invention is as follows.

The method for patterning the organic layer according to this embodiment includes:

(1) forming the protective layer on the organic layer;

(2) forming the photo-sensitive layer on the protective layer on the opposite side of the organic layer;

(3) exposing the photo-sensitive layer;

(4) developing photo-sensitive layer with use of the developing solution that contains the organic solvent, to form a mask pattern;

(5) removing the protective layer and the organic layer in a non-masked area; and

(6) removing the protective layer with use of the stripping solution.

### <(1) Forming Protective Layer on Organic Layer>

The method for patterning the organic layer according to this embodiment includes forming the protective layer on the organic layer. This process usually comes next to formation of the organic layer on the base. In this case, the protective layer is formed on the organic layer on the opposite side of the base. Although the protective layer is preferably formed in direct contact with the organic layer, any other layer may be interposed in between, without departing the spirit of this invention. Such other layer is exemplified by a fluorine-containing undercoat layer. Only one layer, or two or more layers of the protective layer may be provided. The protective layer is preferably formed by using the protective layer forming composition, as described previously.

For details of the formation method, the aforementioned method for applying the protective layer forming composition for the laminate of this invention may be referred to.

### <(2) Forming Photo-Sensitive Layer on Protective Layer on Opposite Side of Organic Layer>

After the step (1), the photo-sensitive layer is formed on the protective layer on the face thereof (preferably on the surface) opposite to the face directed to the organic layer.

The photo-sensitive layer is preferably formed, as described previously, by using the photo-sensitive layer forming composition.

For details of the formation method, the aforementioned method for applying the photo-sensitive layer forming composition for the laminate of this invention may be referred to.

### <(3) Exposing Photo-Sensitive Layer>

After the formation of the photo-sensitive layer in step (2), the photo-sensitive layer is exposed. More specifically, for example, the photo-sensitive layer is at least partially irradiated (exposed) with an active ray.

The exposure is preferably conducted so as to form a predetermined pattern. The exposure may be conducted through a photomask, or a predetermined pattern may be directly drawn.

The active ray employed for the exposure preferably has a wavelength of 180 nm or longer and 450 nm or shorter, and is more preferably 365 nm (i-line), 248 nm (KrF laser) or 193 nm (ArF laser).

Light source of the active ray employable here includes low-pressure mercury lamp, high-pressure mercury lamp, ultrahigh-pressure mercury lamp, chemical lamp, laser generator, and light emitting diode (LED).

In a case where the mercury lamps are employed as the light source, active rays such as g-line (436 nm), i-line (365 nm) or h-line (405 nm) is preferably used. In this invention, use of i-line is preferred, in view of effective demonstration of the effect.

In a case where the laser generator is used as the light source, preferred active rays are solid state lasers (YA G) with a wavelength of 343 nm to 355 nm; excimer lasers with a wavelength of 193 nm (ArF laser), 248 nm (KrF laser), or 351 nm (Xe laser); and semiconductor lasers with a wavelength of 375 nm or 405 nm. Among them, more preferred is active ray having a wavelength of 355 nm or 405 nm, from the viewpoint of stability, cost and so forth. Laser may be irradiated on the photo-sensitive layer all at once, or while dividing the process into several times.

The irradiation dose is preferably 40 to 120 mJ, and more preferably 60 to 100 mJ.

Energy density per pulse of the laser is preferably 0.1 mJ/cm² or larger and 10,000 mJ/cm² or smaller. In order to fully cure the coated film, the energy density is preferably 0.3 mJ/cm² or larger, and more preferably 0.5 mJ/cm² or larger. From the viewpoint of suppressing, for example, decomposition of the photo-sensitive layer due to ablation, the irradiation dose is preferably 1,000 mJ/cm² or lower, and more preferably 100 mJ/cm² or lower.

Pulse width is preferably 0.1 nanoseconds (denoted as “ns”, hereinafter) or wider and 30,000 ns or narrower. From the viewpoint of preventing a colored coated film due to ablation, the pulse width is more preferably 0.5 ns or wider, and even more preferably 1 ns or wider. For improved alignment during scanning exposure, the pulse width is more preferably 1,000 ns or shorter, and even more preferably 50 ns or narrower.

When using a laser generator as a light source, laser frequency is preferably 1 Hz or higher and 50,000 Hz or lower, and more preferably 10 Hz or higher and 1,000 Hz or lower.

For further time saving in the exposure, the laser frequency is more preferably 10 Hz or higher, and even more preferably 100 Hz or higher. For higher alignment accuracy during scanning exposure, the laser frequency is more preferably 10,000 Hz or lower, and more preferably 1,000 Hz or lower.

Laser can more easily narrow a focus than a mercury lamps can, and is also advantageous in that use of a photomask for patterning is omissible in the exposure process.

An exposure apparatus is selectable, without special limitation, from commercially available products, exemplified by Callisto (from V-Technology Co., Ltd.), AEGIS (from V-Technology Co., Ltd.), and DF2200G (from DIC Corporation). Also any other apparatuses are suitably used.

The irradiation dose is adjustable as necessary by using a spectral filter such as a short-pass filter, long-pass filter or band-pass filter.

The exposure may be followed by post-exposure baking (PEB) as necessary.

<(4) Developing Photo-Sensitive Layer with Use of Developing Solution that Contains Organic Solvent, to Form Mask Pattern>

After the exposure of the photo-sensitive layer through the photomask in step (3), the photo-sensitive layer is developed with use of the developing solution. The development is preferably negative type.

Details of the developing solution are as described previously regarding the photo-sensitive layer.

Methods applicable to the development include a method of dipping the base in a bath filled with the developing solution for a certain period of time (dipping); a method of retaining, by surface tension, the developing solution on the surface of the base, and allowing it to stand still for a certain period of time (puddling); a method of spraying the developing solution over the surface of the base (spraying); and a method of continuously ejecting the developing solution through an ejection nozzle which is scanned over the base rotated at a constant rate (dynamic dispensing).

In a case where any of the aforementioned methods of development contains a process of ejecting the developing solution through a development nozzle of a development apparatus towards the photo-sensitive layer, the developing solution is preferably ejected at an ejection pressure (flow rate of the developing solution per unit area) of preferably 2 mL/sec/mm² or lower, more preferably 1.5 mL/sec/mm² or lower, and even more preferably 1 mL/sec/mm² or lower. The lower limit value of the ejection pressure, although not specifically limited, is preferably 0.2 mL/sec/mm² or above, taking the throughput into consideration. With the ejection pressure of the developing solution to be ejected controlled within the aforementioned range, pattern defects ascribed to residue of the resist after the development will be distinctively reduced.

While details of this mechanism remain unclear, the ejection pressure controlled within the aforementioned range would suitably reduce the pressure of the developing solution applied to the photo-sensitive layer, and would suppress the resist pattern on the photo-sensitive layer from being accidentally eroded or decayed.

Note that the ejection pressure of the developing solution (mL/sec/mm²) is given by a value measured at the outlet of the development nozzle of the development apparatus.

Methods of controlling the ejection pressure of the developing solution are exemplified by a method of controlling the ejection pressure with use of a pump or the like, and a method of controlling the pressure through pressure control of the developing solution fed from a pressurized tank.

The development with use of the developing solution that contains the organic solvent may be followed by replacement with other organic solvent, to terminate the development.

### <(5) Removing Protective Layer and Organic Layer in Non-Masked Area>

After developing the photo-sensitive layer to form the mask pattern, the protective layer and the organic layer are removed by etching, at least in the non-masked area. The non-masked area is an area not masked by the mask pattern that is formed by developing the photo-sensitive layer (area from which the photo-sensitive layer is removed by development).

The etching may be conducted in multiple stages. For example, the protective layer and the organic layer may be removed by a single run of etching, or, at least a part of the protective layer may be removed by etching, and then the organic layer (and the residue of the protective layer if necessary) may be removed by another run of etching.

The etching may be dry etching or wet etching. The etching process may alternatively be divided into multiple runs for dry etching and wet etching. For example, the protective layer may be removed either by dry etching or wet etching.

Methods of removing the protective layer and the organic layer may be exemplified by a method “A” in which the protective layer and the organic layer are removed by a single run of dry etching: and a method “B” in which at least a part of the protective layer is removed by wet etching, and then the organic layer (and the residue of the protective layer if necessary) is removed by dry etching.

The dry etching in the method “A”, and the wet etching and the dry etching in the method “B”, may be conducted according to any of known etching methodologies.

One embodiment of the method “A” will be detailed below. For a specific example of the method “B”, the description of JP-2014-098889 A, for example, may be referred to.

In the method “A”, the protective layer and the organic layer in the non-masked area may be removed, more specifically, by dry etching with use of the resist pattern as an etching mask (mask pattern). Representative examples of dry etching are described in JP-S59-126506 A, JP-S59-046628 A, JP-S58-009108 A, JP-S58-002809 A, JP-S57-148706 A, and JP-S1-041102 A.

The dry etching is conducted according to an embodiment below, from the viewpoint of making the cross-sectional shape of the patterned organic layer closer to a rectangular shape, and of reducing damage to the organic layer.

A preferred embodiment includes first stage etching in which the protective layer is etched by using a mixed gas of a fluorine-containing gas and oxygen gas (O₂), to a degree (depth) not allowing the organic layer to expose; and second stage etching following the first stage etching, in which the protective layer is etched by using a mixed gas of nitrogen gas (N₂) and oxygen gas (O₂), preferably to a degree (depth) where the organic layer exposes; and over-etching in which the exposed organic layer is etched. The following paragraphs will explain specific techniques of the dry etching, as well as the first stage etching, the second stage etching, and the over-etching.

Etching conditions of the dry etching are preferably determined by estimating etching time, by using the techniques below.

(A) Estimate an etchrate (nm/min) in the first stage etching, and an etchrate (nm/min) in the second stage etching.

(B) Estimate individually an etching time a predetermined thickness is etched in the first stage etching, and an etching time a predetermined thickness is etched in the second stage etching.

(C) Conduct the first stage etching for the etching time estimated in (B).

(D) Conduct the second stage etching for the etching time estimated in (B), or alternatively conduct the second stage etching for the etching time determined by end point detection.

(E) Conduct the over-etching for the etching time estimated on the basis of the total time of (C) and (D).

The mixed gas used in the first stage etching preferably contains a fluorine-containing gas and oxygen gas (O₂), from the viewpoint of shaping the organic material to be etched into a rectangular shape. In the first stage etching, the laminate is etched to a degree not allowing the organic layer to expose. Hence, the organic layer in this stage is considered to be not damaged yet, or damaged only slightly.

Meanwhile, in the second stage etching and the over-etching, a mixed gas of nitrogen gas and oxygen gas is preferably used, from the viewpoint of avoiding damage on the organic layer.

It is critical to determine the ratio of the amount of etching in the first stage etching and the amount of etching in the second stage etching, so that the organic layer can keep a good rectangularity of the cross-sectional shape attained in the first stage etching.

Note that the ratio of the amount of etching in the second stage etching, relative to the total amount of etching (total of the amount of etching in the first stage etching and the amount of etching in the second stage etching), is preferably 0% or larger and 50% or smaller, and more preferably 10 to 20%. The amount of etching means a value estimated on the basis of a difference between the thickness of the film remained after the etching and the initial film thickness before etched.

The etching preferably includes the over-etching. The over-etching is preferably conducted while determining an over-etching ratio.

The over-etching ratio, although freely determinable, is preferably 30% or less of the overall etching time in the etching process, from the viewpoint of etching resistance of the photoresist and maintenance of the rectangularity of the etched pattern (organic layer), which is more preferably 5 to 25%, and particularly preferably 10 to 15%.

<(6) Removing Protective Layer with Use of Stripping Solution>

After the etching, the protective layer is removed with use of the stripping solution (water, for example).

Details of the stripping solution are as described previously regarding the description on the protective layer.

An exemplary method of removing the protective layer with use of the stripping solution is such as spraying the stripping solution through a spray-type or shower-type ejection nozzle against the resist pattern, to remove the protective layer. Pure water is suitably applicable to the stripping solution. The ejection nozzle is exemplified by an ejection nozzle whose ejection range covers the entire area of the base, of a moving-type ejection nozzle whose travel range covers the entire area of the base. In another possible embodiment, the protective layer is mechanically peeled off, and residue of the protective layer that remains on the organic layer is removed by dissolution.

With use of the moving-type ejection nozzle, the resist pattern is more effectively removed under ejection of the stripping solution, while moving the nozzle from the center of the base towards the edge of the base twice or more, during removal of the protective layer.

The removal of the protective layer is also preferably followed by drying or the like. Drying temperature is preferably 80 to 120° C.

### (Applications)

The laminate of this invention is applicable to manufacture of electronic devices that make use of organic semiconductor. Now the electronic device is understood to be a device that contains a semiconductor, and two or more electrodes which can control current or voltage that occurs between them, with use of electricity, light, magnetism, chemical substance or the like; or a device that can generate electricity, light, magnetism or the like, in response to applied voltage or current.

The electronic device is exemplified by organic photo-electric converter, organic field effect transistor, organic electroluminescence device, gas sensor, organic rectifier, organic inverter, and information recording device.

The organic photo-electric conversion device is applicable to either photo detection or energy conversion (solar battery).

Among them, preferred applications include organic field effect transistor, organic photo-electric converter and organic electroluminescence device; and more preferred is organic field effect transistor, or organic photo-electric converser; and even more preferred is organic field effect transistor.

### EXAMPLES

This invention will further be detailed referring to Examples. Materials, amounts of consumption, ratios, process details, process procedures and so forth described in Examples below may suitably be modified without departing from the spirit of this invention. Also note that “%” and “part(s)” are on the mass basis, unless otherwise specifically mentioned.

Weight-average molecular weight (Mw) of water-soluble resins such as polyvinyl alcohol was calculated as polyether oxide equivalent value measured by GPC with use of HLC-8220 (from Tosoh Corporation) as an apparatus, and SuperMultipore PW-N (from Tosoh Corporation) as a column.

Weight-average molecular weight (Mw) of water-insoluble resin such as (meth)acryl resin was calculated as polystyrene equivalent value measured by GPC with use of HLC-8220 (from Tosoh Corporation) as an apparatus, and TSKgel Super AWM-H (from Tosoh Corporation, 6.0 mm ID×15.0 cm) as a column.

### Syntheses of Resins

### Exemplary Synthesis 1: Synthesis of P-1

Six grams of polyvinyl alcohol (PVA-117, from Kuraray Co., Ltd.) was dissolved in 80 g of pure water, to which 4 g of N-vinyl-2-pyrrolidone (NVP, from Tokyo Chemical Industry Co., Ltd.) was added, the content was mixed, and deoxidized under nitrogen purge. The reaction system was then adjusted to 70° C., to which 1 mg of 1% by mass copper sulfate, 0.1 g of 28% by mass ammonia water, and 0.15 g of a 30% by mass aqueous hydrogen peroxide solution (450 ppm (mass basis) relative to the total mass of the reaction system), and was allowed to start polymerization. During the polymerization, the temperature was controlled to 70 to 80° C., pH was kept at pH5.5 to 6.5 with ammonia water, and 0.15 g of a 30% by mass aqueous hydrogen peroxide solution was added 10 times at 15 minute intervals. The polymerization ratio was found to be 90% or larger. Concentration of hydrogen peroxide during the process was found to be 600 ppm or lower. Next, for residual NVP treatment, 4 g of a 30% by mass aqueous hydrogen peroxide solution was added to proceed the reaction, while adding ammonia water to keep the pH at 5 or higher, for 210 minutes in total, to obtain an aqueous solution of resin P-1.

Resin P-1 is equivalent to polyvinyl alcohol-graft-polyvinylpyrrolidone.

### Exemplary Synthesis 2: Synthesis of P-2

In a reaction vessel, placed were 2 g of pullulan (weight average molecular weight=100,000), 5 ml of vinyl acetate, 5 ml of aqueous solution of ceric ammonium nitrate (10×10⁻³ mol/L), and 80 ml of water, and the mixture was allowed to polymerize at a polymerization temperature of 35° C. for a reaction time of 90 minutes. The polymerization product was washed with water, dried under reduced pressure, extracted with acetone, to obtain a polymer. The polymer was dissolved in methanol, to which a 10% by mass sodium hydroxide solution in methanol was added at 30° C., and 40 minutes after, 10 ml of a 1% by mass aqueous acetic acid solution was added to terminate the reaction, and methanol was evaporated off, to obtain resin P-2.

Resin P-2 is equivalent to pullulan-graft-polyvinyl alcohol.

### Exemplary Synthesis 3: Synthesis of P-3

In a reaction vessel, placed were 2 g of cellulose (weight average molecular weight=100,000), 5 ml of vinyl acetate, 5 ml of aqueous solution of ceric ammonium nitrate (10×10⁻³ mol/L), and 80 ml of water, and the mixture was allowed to polymerize at a polymerization temperature of 35° C. for a reaction time of 90 minutes. The polymerization product was washed with water, dried under reduced pressure, extracted with acetone, to obtain a polymer. The polymer was dissolved in methanol, to which a 10% by mass sodium hydroxide solution in methanol was added at 30° C., and 40 minutes after, 10 ml of a 1% by mass aqueous acetic acid solution was added to terminate the reaction, and methanol was evaporated off, to obtain resin P-3.

Resin P-3 is equivalent to cellulose-graft-polyvinyl alcohol.

### Exemplary Synthesis 4: Synthesis of P-4

Into a vessel, 0.30 mol of 2-methoxyethyl vinyl ether, 0.8 mol of ethyl acetate, 3.2 mmol of 1-butoxyethyl acetate and 100 g of toluene were placed, and upon reaching of the system temperature to 0° C., an 1% by mass ethylaluminum sesquichloride (Et_{1.5}AlCl_{1.5}, 16 mmol) solution in toluene was added to start polymerization. After an elapse of 1.8 hours, a 10% by mass solution of partially saponified polyvinyl acetate (degree of polymerization=500, degree of saponification=10 mol %) in toluene was added so that the number of moles of hydroxy group of the partially saponified polyvinyl acetate amounts twice as much as Et_{1.5}AlCl_{1.5} (32 mmol), to terminate the polymerization reaction. The partially saponified polyvinyl chloride, used herein as a polymerization terminator, was a dehydration purified product from which impurities such as base was preliminarily removed, and then lyophilized from benzene. Five minutes after the termination of polymerization, methanol was added, the solution was further diluted with dichloromethane, and washed with water to remove residue of the initiator. The solution was then concentrated, and dried under reduced pressure, to collect a produced graft polymer, named resin P-4.

Resin P-4 is equivalent to polyvinyl alcohol-graft-polyvinyl alcohol.

### Synthesis of Resin A-1 (Mw=45,000)

Into a three-necked flask equipped with a nitrogen feeding tube and a condenser, PGMEA (propylene glycol monomethyl ether acetate, 32.62 g) was placed, and the content was heated to 86° C. To the content, a solution obtained by dissolving BzMA (benzyl methacrylate, 16.65 g), THFMA (tetrahydrofuran-2-yl methacrylate, 21.08 g), t-BuMA (t-butyl methacrylate, 5.76 g), and V-601 (0.4663 g, from FUJIFILM Wako Pure Chemical Corporation) in PGMEA (32.62 g) was added dropwise over 2 hours. The reaction liquid was then stirred for 2 hours, and the reaction was terminated. The reaction liquid was re-precipitated in heptane, and the produced white powder was collected by filtration, to obtain resin A-1. The weight average molecular weight (Mw) was found to be 45,000. Resin A-1 is equivalent to the aforementioned photo-sensitive layer forming specific resin.

### (Other Components)

Components of the protective layer forming composition, or, photo-sensitive layer forming composition listed in Table 1 are as follows.

### <Protective Layer Forming Composition>

PO-1: Eighty parts by mass of Pitzcol V-7154 (from DKS Co., Ltd.), and, 20 parts by mass of Pitzcol K-30 (from DKS Co., Ltd.) were used in combination.

Pitzcol V-7154 is equivalent to polyvinyl alcohol-graft-polyvinylpyrrolidone.

Pitzcol K-30 is equivalent to polyvinylpyrrolidone.
PO-2: Resin P-1 was used alone.
PO-3: Pitzcol V-7154 was used alone.
PO-4: Resin P-2 was used alone.
PO-5: Resin P-3 was used alone.
PO-6: Pullulan (from DKS Co., Ltd.) and xanthane (Sansho Co., Ltd.) were mixed for use.

Xanthane (xanthane gum) is a branched polysaccharide.
PO-7: Ninety-five parts by mass of Pitzcol V-7154, and, 5 parts by mass of PXP-05 (from Japan VAM & POVAL Co., Ltd.) were used in combination.
PO-8: Resin P-4 was used alone.
RO-1: Fifty parts by mass of PVA (PXP-05, from Japan VAM & POVAL Co., Ltd.), and, 50 parts by mass of PVP (Pitzcol K-90, from DKS Co., Ltd.) were used in combination.
RO-2: Fifty parts by mass of PVA (PXP-05, from Japan VAM & POVAL Co., Ltd.), and, 50 parts by mass of PEG (polyethylene glycol 20000, from FUJIFILM Wako Pure Chemical Corporation) were used in combination.
RO-3: PVA (K-30, from DKS Co., Ltd.) was used alone.
RO-4: PVA (PXP-05, from Japan VAM & POVAL Co., Ltd.) was used alone.
Surfactant E00: Acetylenol E00, from Kawaken Fine Chemicals Co., Ltd., compound represented by Formula (E00) below
Solvent water: Pure water

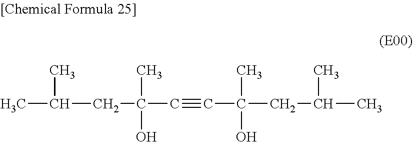 [SMILES: CC(C)CC(C)(O)C#CC(C)(O)CC(C)C]

### <Photo-Sensitive Layer Forming Composition>

Resin A-1: Resin A-1 described above.
Photo-acid generator B-1: A compound represented by Formula (OS-107) below, with R¹¹=tolyl group, and R¹⁸=methyl group was employed.
Quencher (basic compound) Y: A thiourea derivative represented by Formula (Yl) below.
Surfactant PF-6320: from OMNOVA Solutions Inc., PF-6320
Solvent PGMEA: propylene glycol monomethyl ether acetate

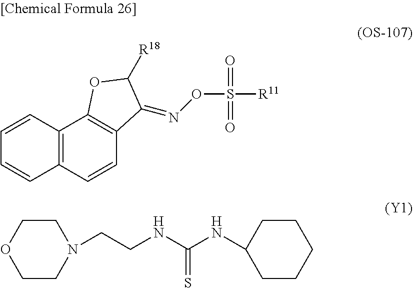

### Examples and Comparative Examples

In the individual Examples and Comparative Examples, conducted were preparation of the protective layer forming composition, preparation of the photo-sensitive layer forming composition, formation of the organic semiconductor layer, formation of the protective layer, and formation of the photo-sensitive layer, to manufacture the individual multi-layered bodies.

The protective layer and the pattern formation were evaluated by the methods below.

### <Preparation of Protective Layer Forming Composition>

The individual components listed in Table 1, in the rows headed “Protective layer” and sub-headed “Forming composition”, were mixed according to ratios (% by mass) given in Table 1 to prepare each homogeneous solution, and the solution was then filtered through Savana PP (polypropylene) Cartridge Filter (0.1 μm equivalent) from Entegris, Inc., to prepare each water-soluble resin composition (protective layer forming composition).

For example, notation of PO-1 given in Table 1, in the row headed “Resin” and sub-headed “Type” means that aforementioned Pitzcol V-7154 and Pitzcol K-30 were used at the aforementioned ratio, with the total amount given in the row headed “Resin” and sub-headed “% by mass”.

In Table 1, notation “-” represents that there is no corresponding component.

### <Preparation of Photo-Sensitive Layer Forming Composition>

The individual components listed in Table 1, in the rows headed “Photo-sensitive layer” and sub-headed “Forming composition”, were mixed according to ratios (% by mass) given in Table 1 to prepare each homogeneous solution, and the solution was then filtered through Savana PP Cartridge Filter (0.1 μm equivalent) from Entegris, Inc., to prepare each photo-sensitive layer forming composition.

### <Manufacture of Base>

ITO (indium tin oxide) was deposited by evaporation on one face of a 5-inch-diameter, disk-like silicon wafer (1 inch=2.54 cm), to manufacture a base.

More specifically, in CM616 evaporation apparatus from Canon Tokki Corporation, a powdery organic material was evaporated in vacuo under heating with a heater, and allowed to deposit at a rate of 0.05 nm/min on the surface of the substrate, to form a thin film.

### <Manufacture of Organic Layer>

In the cases denoted as “HAT-CN” in Table 1 in the row headed “Organic layer” and sub-headed “Type”, HAT-CN (2,3,6,7,10,11-hexacyano-1,4,5,8,9,12-hexaazatriphenylene) was deposited by evaporation on the surface of the base already having ITO deposited thereon, to form an organic layer (organic semiconductor layer). Thickness of the organic layer was listed in Table 1 in the row headed “Organic layer” and sub-headed “Film thickness (nm)”.

More specifically, in CM616 evaporation apparatus from Canon Tokki Corporation, a powdery organic material was evaporated in vacuo under heating with a heater, and allowed to deposit at a rate of 0.05 nm/min on the surface of the substrate, to form a thin film.

### <Evaluation of Protective Layer 1>

Each protective layer forming composition was spin-coated (1,500 rpm (revolutions per minutes), 30 seconds) over the surface of the organic layer, dried at temperature listed in Table 1 in a row headed “Protective layer” and sub-headed “Baking temperature (° C.)” for one minute, to form each protective layer having a thickness (film thickness (μm)) listed in Table 1.

The surface of the protective layer was observed under an optical microscope to check whether there were any crack (crack in the protective layer) or striation (streak-like coating defect), and evaluated according to the evaluation criteria below. Results of evaluation are summarized in Table 1 in the row headed “Evaluation of protective layer 1”. Result of evaluation A or B (preferably A) is understood that the protective layer excels in surface profile.

### [Evaluation Criteria]

A: Neither crack nor striation observed;
B: either crack or striation observed; and
C: both crack and striation observed.

### <Evaluation of Protective Layer 2>

The base, the organic layer the and protective layer were produced in the same way as described in “Evaluation of Protection Layer 1”, except that the silicon wafer employed here was a 4-inch-diameter, disk-like silicon wafer having, formed over the entire surface of which, a periodic rectangular pattern of 60 μm long, 20 μm wide and 1 μm high.

The surface of the protective layer was visually observed to check whether there were any crack or striation, and evaluated according to the evaluation criteria below. Results of evaluation are summarized in Table 1 in the row headed “Evaluation of protective layer 2”.

Result of evaluation A or B (preferably A) is understood that the protective layer excels in step coverage of the protective layer.

### [Evaluation Criteria]

A: Neither crack nor striation observed;
B: either crack or striation observed; and
C: both crack and striation observed.

### <Evaluation of Protective Layer 3>

The base, the organic layer and the protective layer were produced in the same way as described in “Evaluation of Protective Layer 1”. The surface of the thus produced protective layer was plasma treated (800 W, oxygen 500 ml/s, nitrogen 25 ml/s) for 20 seconds, and thickness of the residual protective layer (Thickness 1) was measured by using stylus profiler Dektak, from Bruker Corporation.

Water was applied as the stripping solution to the surface of the plasma-treated protective layer for 20 seconds. Thickness of the residual protective layer (Thickness 2) was then measured in the same way as Thickness 1.

Dissolution rate was then calculated on the basis of difference between Thickness 1 and Thickness 2, and evaluated according to the evaluation criteria below. Results are summarized in Table 1 in the row headed “Evaluation of Protective Layer 3”.

It is considered that the larger the dissolution rate, the less likely the dissolution rate of the protective layer to change. If the dissolution rate hardly changes after the plasma treatment, the protective layer is considered less likely to change the dissolution rate, even if exposed to an etching gas such as O₂ gas.

### [Evaluation Criteria]

A: Dissolution rate found to be 0.1 μm/s or faster;
B: dissolution rate found to be 0.05 μm/s or faster and slower than 0.1 μm/s;
C: dissolution rate found to be 0.01 μm/s or faster and slower than 0.05 μm/s; and
D: dissolution rate found to be slower than 0.01 μm/s.

### <Evaluation of Pattern Formation 1>

### [Production of Base, Organic Layer and Protective Layer]

The base, the organic layer and the protective layer were produced in the same way as described in “Evaluation of Protective Layer 1”.

### [Formation of Photo-Sensitive Layer]

Over the surface of the thus formed protective layer, each photo-sensitive layer forming composition was spin-coated, dried at temperature listed in Table in the row headed “Photo-sensitive layer” and sub-headed “Baking temperature (° C.)” for one minute, to form each photo-sensitive layer having a thickness (film thickness (μm)) listed in Table 1, thereby obtaining each laminate.

### [Evaluation of Protective Layer 1]

The photo-sensitive layer was exposed to i-line with use of an i-line Step-and-Repeat System NSR2005i9C (from Nikon Corporation), under optical conditions of NA=0.50 and σ=0.60. Irradiation dose was set to a value listed in Table 1 in the row headed “Irradiation dose (mJ)”.

Exposure was conducted through a binary mask having a 1:1 line-and-space pattern with a line width of 10 μm.

The photo-sensitive layer was then heated at a temperature listed in Table 1 in the row headed “PEB temperature (° C.)” for 60 seconds, developed with butyl acetate (nBA) for 50 seconds, and spin-dried to obtain a photo-sensitive layer pattern.

The substrate was dry-etched through the photo-sensitive layer pattern used as a mask according to the conditions below, and the protective layer in the non-masked area and the organic layer in the non-masked area were removed.

Conditions: source power=500 W, gas: oxygen flow rate=100 ml/min, time=3 minutes

The resultant substrate was washed with water to remove the pattern made of the protective layer, dried in vacuo for 5 hours so as to remove water that remains on the organic layer, and so as to repair, by drying, any damage caused during the process. The substrate having the organic layer patterned thereon was obtained.

The substrate was then observed to check whether there were any residue of the protective layer remained on the organic layer pattern, and evaluated according to the evaluation criteria below. Results of evaluation are summarized in Table 1 in the row headed “Evaluation of Residue of Protective Layer 1”.

### —Evaluation Criteria—

A: Residue of protective layer not observed; and
B: residue of protective layer observed.

### [Evaluation of Protective Layer 2]

A photo-sensitive layer pattern was obtained in the same way as described in “Evaluation of Pattern Formation 1”, except that a mask used for the exposure was changed to a binary mask having a 1:1 line-and-space pattern with a line width of 100 μm.

The work was further developed with water for 20 seconds, and spin-dried to obtain patterned photo-sensitive layer and protective layer, having a 1:1 line-and-space pattern with a line width of 100 μm.

The substrate was then dry-etched through the patterned photo-sensitive layer and the protective layer used as a mask according to the conditions below, to remove the organic layer in the non-masked area.

Conditions: source power=500 W, gas: oxygen flow rate=100 m1/min, time=3 minutes

The resultant substrate was spin-washed with water to remove the pattern made of the protective layer, dried in vacuo for 5 hours so as to remove water that remained on the organic layer, and so as to repair, by drying, any damage caused during the process. The substrate having the organic layer patterned thereon was thus obtained.

The substrate was then observed to check whether there were any residue of the protective layer remained on the organic layer pattern, and evaluated according to the evaluation criteria below. Results of evaluation are summarized in Table 1 in the row headed “Evaluation of Residue of Protective Layer 2”.

### —Evaluation Criteria—

A: Residue of protective layer not observed; and
B: residue of protective layer observed.

TABLE 1

| | | | | [symbol] | | | | | | | | [symbol] | | | |
|---|---|---|---|---|---|---|---|---|---|---|---|---|---|---|---|
| | | | | 1 | 2 | 3 | 4 | 5 | 6 | 7 | 8 | 1 | 2 | 3 | 4 |
| base | Type | | | ITO | ITO | ITO | ITO | ITO | ITO | ITO | ITO | ITO | ITO | ITO | ITO |
| | Forming method | | | Vapor | Vapor | Vapor | Vapor | Vapor | Vapor | Vapor | Vapor | Vapor | Vapor | Vapor | Vapor |
| | | | | deposition | deposition | deposition | deposition | deposition | deposition | deposition | deposition | deposition | deposition | deposition | deposition |
| organic layer | Type | | | HAT-CN | HAT-CN | HAT-CN | HAT-CN | HAT-CN | HAT-CN | HAT-CN | HAT-CN | HAT-CN | HAT-CN | HAT-CN | HAT-CN |
| | Thicknesss (nm) | | | 100 nm | 100 nm | 100 nm | 100 nm | 100 nm | 100 nm | 100 nm | 100 nm | 100 nm | 100 nm | 100 nm | 100 nm |
| | Forming method | | | Vapor | Vapor | Vapor | Vapor | Vapor | Vapor | Vapor | Vapor | Vapor | Vapor | Vapor | Vapor |
| | | | | deposition | deposition | deposition | deposition | deposition | deposition | deposition | deposition | deposition | deposition | deposition | deposition |
| protective layer | forming | Resin | Type | PO-1 | PO-2 | PO-3 | PO-4 | PO-5 | PO-6 | PO-7 | PO-8 | RO-1 | RO-2 | RO-3 | RO-4 |
| | composition | | mass % | 9.9 | 9.9 | 9.9 | 9.9 | 9.9 | 9.9 | 9.9 | 9.9 | 9.9 | 9.9 | 9.9 | 9.9 |
| | | Surfactant | Type | E00 | E00 | E00 | E00 | E00 | E00 | E00 | E00 | E00 | E00 | E00 | E00 |
| | | | mass % | 0.1 | 0.1 | 0.1 | 0.1 | 0.1 | 0.1 | 0.1 | 0.1 | 0.1 | 0.1 | 0.1 | 0.1 |
| | | solvent | Type | water | water | water | water | water | water | water | water | water | water | water | water |
| | | | mass % | 90 | 90 | 90 | 90 | 90 | 90 | 90 | 90 | 90 | 90 | 90 | 90 |
| | Thickness (μm) | | | 1.5 | 1.5 | 1.5 | 1.5 | 1.5 | 1.5 | 1.5 | 1.5 | 1.5 | 1.5 | 1.5 | 1.5 |
| | Baking temperature (° C.) | | | 70 | 70 | 70 | 70 | 70 | 70 | 70 | 70 | 70 | 70 | 70 | 70 |
| photo-sensitive | forming | Resin | Type | A-1 | A-1 | A-1 | A-1 | A-1 | A-1 | A-1 | A-1 | A-1 | A-1 | A-1 | A-1 |
| layer | composition | | mass % | 24.58 | 24.58 | 24.58 | 24.58 | 24.58 | 24.58 | 24.58 | 24.58 | 24.58 | 24.58 | 24.58 | 24.58 |
| | | photo-acid | Type | B-1 | B-1 | B-1 | B-1 | B-1 | B-1 | B-1 | B-1 | B-1 | B-1 | B-1 | B-1 |
| | | generator | mass % | 0.26 | 0.26 | 0.26 | 0.26 | 0.26 | 0.26 | 0.26 | 0.26 | 0.26 | 0.26 | 0.26 | 0.26 |
| | | Quencher | Type | Y | Y | Y | Y | Y | Y | Y | Y | Y | Y | Y | Y |
| | | | mass % | 0.8 | 0.8 | 0.8 | 0.8 | 0.8 | 0.8 | 0.8 | 0.8 | 0.8 | 0.8 | 0.8 | 0.8 |
| | | Surfactant | Type | PF-6320 | PF-6320 | PF-6320 | PF-6320 | PF-6320 | PF-6320 | PF-6320 | PF-6320 | PF-6320 | PF-6320 | PF-6320 | PF-6320 |
| | | | mass % | 0.08 | 0.08 | 0.08 | 0.08 | 0.08 | 0.08 | 0.08 | 0.08 | 0.08 | 0.08 | 0.08 | 0.08 |
| | | solvent | Type | PGMEA | PGMEA | PGMEA | PGMEA | PGMEA | PGMEA | PGMEA | PGMEA | PGMEA | PGMEA | PGMEA | PGMEA |
| | | | mass % | 75 | 75 | 75 | 75 | 75 | 75 | 75 | 75 | 75 | 75 | 75 | 75 |

| | | | | | | | | | | | | | |
|---|---|---|---|---|---|---|---|---|---|---|---|---|---|
| | Thickness (μm) | 1.8 | 1.8 | 1.8 | 1.8 | 1.8 | 1.8 | 1.8 | 1.8 | 1.8 | 1.8 | 1.8 | 1.8 |
| | Baking temperature (° C.) | 50 | 50 | 50 | 50 | 50 | 50 | 50 | 50 | 50 | 50 | 50 | 50 |
| process | Irradiation dose (ml) | 120 | 120 | 120 | 120 | 120 | 120 | 120 | 120 | 120 | 120 | 120 | 120 |
| | PEB temperature (° C.) | 50 | 50 | 50 | 50 | 50 | 50 | 50 | 50 | 50 | 50 | 50 | 50 |
| | devoloping solution | nBA | nBA | nBA | nBA | nBA | nBA | nBA | nBA | nBA | nBA | nBA | nBA |
| | Stripping method | water Spin | water Spin | water Spin | water Spin | water Spin | water Spin | water Spin | water Spin | water Spin | water Spin | water Spin | water Spin |
| | Evaluation of protective layer 1 | A | A | A | A | A | A | A | A | A | A | C | A |
| | Evaluation of protective layer 2 | A | A | A | A | A | A | A | A | B | B | C | A |
| | Evaluation of protective layer 3 | A | B | B | B | B | B | A | B | C | C | D | C |
| | Evaluation of Residue | A | A | A | A | A | A | A | A | B | B | B | B |
| | of Protective Layer 1 | | | | | | | | | | | | |
| | Evaluation of Residue | A | A | A | A | A | A | A | A | B | B | B | B |
| | of Protective Layer 2 | | | | | | | | | | | | |

It is understood from the results summarized in Table 1 that Examples that employed the laminate of this invention were found to cause small change in the dissolution rate of the protective layer, as compared with the cases where the multi-layered bodies of Comparative Examples were employed.

It is also understood that the multi-layered bodies of Comparative Example 1 to Comparative Example 4, whose resins contained in the protective layer have neither a branched part nor a molecular chain bonded to the branched part, demonstrated large change in the dissolution rate of the protective layer.

What is claimed is:

1. A laminate comprising a base, an organic layer, a protective layer and a photo-sensitive layer in this order,
the protective layer containing a resin,
the resin having a branched part and a molecular chain bonded to the branched part,
the resin being a water-soluble resin,
the photo-sensitive layer being intended for development with use of a developing solution, and
the protective layer being intended for stripping with use of a stripping solution.

2. The laminate of claim 1, wherein the molecular chain has at least one repeating unit from among repeating units represented by any of Formula (1-1) to Formula (5-1) below; 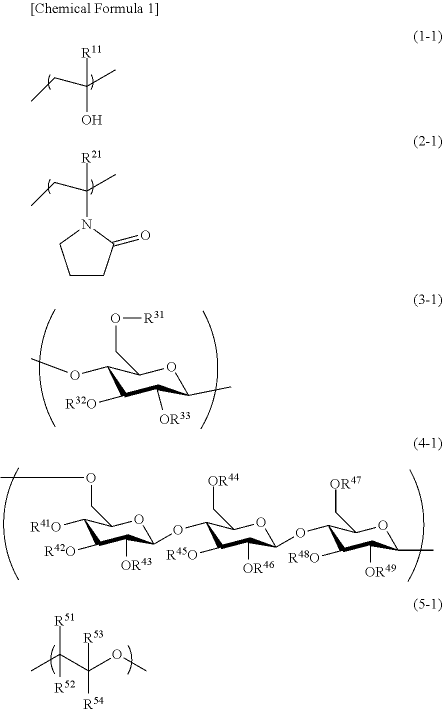
in Formula (1-1) to Formula (5-1), R¹¹ represents a hydrogen atom or a methyl group, R²¹ represents a hydrogen atom or a methyl group, each of R³¹ to R³³ independently represents a substituent or a hydrogen atom, each of R⁴¹ to R⁴⁹ independently represents a substituent or a hydrogen atom, and each of R⁵¹ to R⁵⁴ independently represents a hydrogen atom or a substituent.

3. The laminate of claim 1, wherein the resin is a water-soluble resin.

4. The laminate of claim 1, wherein a component ratio the repeating unit in the molecular chain is 10 mol % or more different from a component ratio of the repeating unit in other molecular chain in the resin.

5. The laminate of claim 1, wherein the molecular chain has a repeating unit represented by Formula (1-1), or, a repeating unit represented by Formula (2-1).

6. The laminate of claim 1, wherein the resin is polyvinyl alcohol-graft-polyvinylpyrrolidone, or, polyethylene glycol-graft-polyvinyl alcohol.

7. The laminate of claim 1, wherein the protective layer further contains other resin different from the resin.

8. The laminate of claim 1, wherein the development is of negative type.

9. The laminate of claim 1, wherein the developing solution contains an organic solvent whose content, relative to the total mass of the developing solution, is 90 to 100% by mass.

10. A composition intended for use in forming the protective layer contained in the laminate described in claim 1, the composition comprising:
a resin,
the resin having a branched part and a molecular chain bonded to the branched part, and
the resin being a water-soluble resin.

11. A composition intended for use in forming the photo-sensitive layer contained in the laminate described in claim 1.

12. A laminate forming kit comprising A and B below:
A: a composition intended for use in forming the protective layer contained in the laminate described in claim 1, the composition comprising a resin, the resin having a branched part and a molecular chain bonded to the branched part, and the resin being a water-soluble resin; and
B: a composition intended for use in forming the photo-sensitive layer contained in the laminate described in claim 1.
